(19) United States
(12) Patent Application Publication
(10) Pub. No.: US 2024/0290636 A1
(43) Pub. Date: Aug. 29, 2024

(54) SUBSTRATE TREATING METHOD, SUBSTRATE TREATING APPARATUS, AND TREATMENT LIQUID

(71) Applicant: SCREEN Holdings Co., Ltd., Kyoto (JP)

(72) Inventors: Shogo KUNIEDA, Kyoto (JP); Yuta SASAKI, Kyoto (JP); Yosuke HANAWA, Kyoto (JP)

(21) Appl. No.: 18/693,304

(22) PCT Filed: May 17, 2022
(86) PCT No.: PCT/JP2022/020539

§ 371 Date: Mar. 19, 2024

(30) Foreign Application Priority Data
Sep. 24, 2021 (JP) 2021-155328

(51) Int. Cl. H01L 21/67

(52) U.S. Cl. CPC H01L 21/67034

(57) ABSTRACT

The present invention relates to a substrate treating method, a substrate treating apparatus, and a treatment liquid. The substrate treating method includes the treatment liquid supply step, the solidified film forming step, and the sublimation step. In the treatment liquid supply step, the treatment liquid is supplied to a substrate. The treatment liquid contains a sublimable substance and a solvent. In the solidified film forming step, the solvent evaporates from the treatment liquid on the substrate. In the solidified film forming step, a solidified film is formed on the substrate. The solidified film contains the sublimable substance. In the sublimation step, the solidified film sublimates. The substrate is dried by sublimation of the solidified film. The sublimable substance has a vapor pressure at normal temperatures of 0.1 Pa or more and 1.0 Pa or less.

### TECHNICAL FIELD

The present invention relates to a substrate treating method, a substrate treating apparatus, and a treatment liquid. The substrate is, for example, a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, a solar cell substrate.

### BACKGROUND ART

Patent Literature 1 discloses a substrate treating method for treating a substrate on which a pattern is formed. The substrate treating method includes the treatment liquid supply step, the solidified film forming step, and the sublimation step. In the treatment liquid supply step, a treatment liquid is supplied to a substrate. The treatment liquid contains a solvent and a sublimable substance. In the solidified film forming step, the solvent evaporates from the treatment liquid on the substrate, and a solidified film is formed on the substrate. In the sublimation step, the solidified film sublimates. In the sublimation step, the solidified film changes to gas without being a liquid. The solidified film is removed from the substrate by sublimation of the solidified film. The substrate is dried by sublimation of the solidified film.

Patent Literature 1 further discloses treatment conditions for appropriately treating a substrate. The treatment conditions have a certain range. The range of treatment conditions is also referred to as a process window.

The treatment conditions include conditions of the treatment liquid. The conditions of the treatment liquid relate to, for example, the compounding ratio of the sublimable substance and the solvent. The conditions of the treatment liquid relate to, for example, the concentration of the treatment liquid. The conditions of the treatment liquid have a certain range. The range of conditions of the treatment liquid is one of the process windows. When the treatment liquid satisfies the conditions of the treatment liquid in the substrate treating method, the substrate is appropriately treated. For example, when the treatment liquid satisfies the conditions of the treatment liquid, the pattern on the substrate is protected. When the treatment liquid does not satisfy the conditions of the treatment liquid, the substrate is not appropriately treated. For example, when the treatment liquid does not satisfy the conditions of the treatment liquid, the pattern on the substrate significantly collapses.

### CITATION LIST

### Patent Literature

Patent Literature 1: JP 2020-4948 A

### SUMMARY OF INVENTION

### Technical Problem

In the conventional substrate treating method, the conditions of the treatment liquid are severe. In other words, the range of conditions of the treatment liquid is narrow. The process window for the treatment liquid is narrow.

Therefore, it may be difficult for the treatment liquid to satisfy the conditions of the treatment liquid. For example, it may be difficult to manage the treatment liquid so as to satisfy the conditions of the treatment liquid. As a result, it may be difficult to appropriately treat the substrate. For example, it may be difficult to appropriately protect the pattern on the substrate.

The present invention has been made in consideration of the above situation, and its object is to provide a substrate treating method, a substrate treating apparatus, and a treatment liquid that can appropriately dry substrates.

### Solution to Problem

In order to achieve such an object, the present invention is constituted as stated below. That is, the present invention is a substrate treating method for treating a substrate on which a pattern is formed, the substrate treating method including: a treatment liquid supply step of supplying a treatment liquid containing a sublimable substance and a solvent to the substrate: a solidified film forming step of forming a solidified film containing the sublimable substance on the substrate by evaporating the solvent from the treatment liquid on the substrate; and a sublimation step of sublimating the solidified film; and the sublimable substance having a vapor pressure at normal temperatures of 0.1 Pa or more and 1.0 Pa or less.

The substrate treating method is for treating the substrate on which the pattern is formed. The substrate treating method includes the treatment liquid supply step, the solidified film forming step, and the sublimation step. In the treatment liquid supply step, the treatment liquid is supplied to a substrate. The treatment liquid contains a sublimable substance and a solvent. In the solidified film forming step, the solvent evaporates from the treatment liquid on the substrate. In the solidified film forming step, a solidified film is formed on the substrate. The solidified film contains the sublimable substance. In the sublimation step, the solidified film sublimates. The substrate is dried by sublimation of the solidified film.

Here, the sublimable substance has a vapor pressure at normal temperatures of 0.1 Pa or more and 1.0 Pa or less. Therefore, the conditions of the treatment liquid for appropriately treating the substrate are laxer. In other words, the process window for the treatment liquid is wider. For example, the process window of the treatment liquid containing the sublimable substance having a vapor pressure of 0.1 Pa or more and 1.0 Pa or less at normal temperatures is wider than the process window of the treatment liquid containing the sublimable substance having a vapor pressure of more than 1.0 Pa at normal temperatures. Therefore, it is easier to appropriately dry the substrate.

As described above, according to this substrate treating method, the substrate is appropriately dried.

In the substrate treating method described above, the sublimable substance preferably has a solubility in the solvent of 150 vol % or more at normal temperatures. The conditions of the treatment liquid for appropriately treating the substrate are even laxer. In other words, the process window for the treatment liquid is further wider. For example, the process window of the treatment liquid having a solubility of the sublimable substance in the solvent of 150 vol % or more at normal temperatures is further wider than the process window of the treatment liquid having a solubility of the sublimable substance in the solvent of less than 150 vol % at normal temperatures. Therefore, it is further easier to appropriately dry the substrate.

In the substrate treating method described above, the sublimable substance is preferably 4-tert-butylphenol. 4-tert-butylphenol has a vapor pressure at normal temperatures of 0.1 Pa or more and 1.0 Pa or less. When the sublimable substance is 4-tert-butylphenol, it is suitably satisfied that the sublimable substance has a vapor pressure at normal temperatures of 0.1 Pa or more and 1.0 Pa or less. Therefore, the conditions of the treatment liquid for appropriately treating the substrate are laxer. Therefore, it is easier to appropriately dry the substrate.

In the substrate treating method described above, the sublimable substance is preferably acetophenone oxime. Acetophenone oxime has a vapor pressure at normal temperatures of 0.1 Pa or more and 1.0 Pa or less. When the sublimable substance is acetophenone oxime, it is suitably satisfied that the sublimable substance has a vapor pressure at normal temperatures of 0.1 Pa or more and 1.0 Pa or less. Therefore, the conditions of the treatment liquid for appropriately treating the substrate are laxer. Therefore, it is easier to appropriately dry the substrate.

In the substrate treating method described above, the solvent is preferably isopropyl alcohol. 4-tert-butylphenol has a solubility in isopropyl alcohol of 150 vol % or more at normal temperatures. Acetophenone oxime has a solubility in isopropyl alcohol of 150 vol % or more at normal temperatures. When the solvent is isopropyl alcohol, it is easy to satisfy that the sublimable substance has a solubility in the solvent of 150 vol % or more at normal temperatures. Therefore, the conditions of the treatment liquid for appropriately treating the substrate are even laxer. Therefore, it is further easier to appropriately dry the substrate.

In the substrate treating method described above, it is preferable that a ratio of a volume of the sublimable substance for producing the treatment liquid to a volume of the solvent for producing the treatment liquid is defined as a compounding ratio (vol %), a probability that the pattern on the substrate collapses when the substrate is treated in the treatment liquid supply step, the solidified film forming step, and the sublimation step is defined as a collapse rate (%), the smallest collapse rate among the plurality of collapse rates (%) obtained by changing the compounding ratio is defined as a minimum collapse rate (%), a value obtained by adding 5% to the minimum collapse rate is defined as a first reference value (%), and a range of the compounding ratio when the collapse rate is equal to or less than the first reference value is defined as a first range, and the first range has a width of 10 or more.

When the compounding ratio is within the first range, the collapse rate is equal to or less than the first reference value. The first reference value is a value obtained by adding 5% to the minimum collapse rate. Therefore, when the compounding ratio is within the first range, the collapse rate is low. When the compounding ratio is within the first range, the pattern on the substrate is suitably protected. When the compounding ratio is within the first range, the substrate is appropriately dried.

The first range has a width of 10 or more. The first range has a width of 10 vol % or more. That is, the width of the first range is wide. Here, the compounding ratio is one of the conditions of the treatment liquid. The first range corresponds to the range of conditions of the treatment liquid. The first range corresponds to the process window for the treatment liquid. Therefore, the conditions of the treatment liquid are lax. The process window for the treatment liquid is wide. Therefore, it is easier to properly dry the substrate.

It can also be said that the “compounding ratio” is the ratio of a volume of the sublimable substance used to produce the treatment liquid to a volume of the solvent used to produce the treatment liquid.

The “collapse rate” can also be said to be, for example, a ratio of the collapsed pattern on the substrate to the pattern on the substrate. The pattern includes a plurality of projections. In this case, it can also be said that the “collapse rate” is a ratio of the number of collapsed projections to the number of projections.

“A plurality of collapse rates (%) obtained by changing the compounding ratio” can also be said to be a plurality of collapse rates (%) obtained at different compounding ratios.

“A range of the compounding ratio when the collapse rate is equal to or less than the first reference value” can also be said to be a range of the compounding ratio in which the collapse rate of equal to or less than the first reference value is obtained.

In the substrate treating method described above, it is preferable that when the maximum height of the solidified film is about 2.5 times the height of the pattern, the collapse rate is equal to or less than the first reference value. The maximum height of the solidified film depends on the compounding ratio. When the maximum height of the solidified film is about 2.5 times the height of the pattern, the substrate is appropriately treated. This indicates that the process window for the treatment liquid is even wider. As described above, the process window for the treatment liquid is even wider. Therefore, it is even easier to appropriately dry the substrate.

In the substrate treating method described above, it is preferable that when the maximum height of the solidified film is about 4.0 times the height of the pattern, the collapse rate is equal to or less than the first reference value. The maximum height of the solidified film depends on the compounding ratio. When the maximum height of the solidified film is about 4.0 times the height of the pattern, the substrate is appropriately treated. This indicates that the process window for the treatment liquid is even wider. As described above, the process window for the treatment liquid is even wider. Therefore, it is even easier to appropriately dry the substrate.

In the substrate treating method described above, it is preferable that a ratio of a volume of the sublimable substance for producing the treatment liquid to a volume of the solvent for producing the treatment liquid is defined as a compounding ratio (vol %), a probability that the pattern on the substrate collapses when the substrate is treated in the treatment liquid supply step, the solidified film forming step, and the sublimation step is defined as a collapse rate (%), the smallest collapse rate among the plurality of collapse rates (%) obtained by changing the compounding ratio is defined as a minimum collapse rate (%), the compounding ratio when the collapse rate is the minimum collapse rate is defined as an optimum compounding ratio (vol %), a value obtained by adding 10 vol % to the optimum compounding ratio is defined as a first compounding ratio (vol %), the collapse rate when the compounding ratio is the first compounding ratio is defined as a first collapse rate (%), and a value obtained by adding 10% to the minimum collapse rate is defined as a second reference value (%), and the first collapse rate is lower than the second reference value.

When the compounding ratio is the optimum compounding ratio, the collapse rate is the minimum collapse rate. When the compounding ratio is the first compounding ratio, the collapse rate is the first collapse rate. Here, the first compounding ratio is a value obtained by adding 10 vol % to the optimum compounding ratio.

The first collapse rate is lower than the second reference value. Here, the second reference value is a value obtained by adding 10% to the minimum collapse rate. Therefore, when the compounding ratio increases from the optimum compounding ratio by 10 vol %, the collapse rate increases from the minimum collapse rate by less than 10%. In other words, when the increase amount of the compounding ratio from the optimum compounding ratio is 10%, the increase amount of the collapse rate from the minimum collapse rate is less than 10%. Therefore, when the compounding ratio increases from the optimum compounding ratio by 10 vol %, the collapse rate does not significantly increase. Accordingly, when the compounding ratio is within the range of the optimum compounding ratio to the first compounding ratio, the substrate is appropriately dried.

The range of the compounding ratio from the optimum compounding ratio to the first compounding ratio is 10 vol %. That is, the range of the compounding ratio from the optimum compounding ratio to the first compounding ratio is wide. Here, the compounding ratio is one of the conditions of the treatment liquid. The range of the compounding ratio from the optimum compounding ratio to the first compounding ratio corresponds to the range of conditions of the treatment liquid. The range of the compounding ratio from the optimum compounding ratio to the first compounding ratio corresponds to the process window for the treatment liquid. Therefore, the conditions of the treatment liquid are lax. The process window for the treatment liquid is wide. Therefore, it is easier to properly dry the substrate.

“A compounding ratio when the collapse rate is the minimum collapse rate” can also be said to be a compounding ratio at which the minimum collapse rate is obtained.

In the substrate treating method described above, the minimum collapse rate is preferably 5% or less.

As described above, when the compounding ratio is within the first range, the collapse rate is equal to or less than the first reference value. Here, when the minimum collapse rate is 5% or less, the first reference value is 10% or less. Therefore when the compounding ratio is within the first range, the collapse rate is 10% or less. Accordingly, when the compounding ratio is within the first range, the collapse rate is low. When the compounding ratio is within the first range, the pattern on the substrate is suitably protected. Therefore, it is easier to appropriately dry the substrate.

When the compounding ratio is the optimum compounding ratio, the collapse rate is the minimum collapse rate. When the compounding ratio is the first compounding ratio, the collapse rate is the first collapse rate lower than the second reference value. Here, when the minimum collapse rate is 5% or less, the second reference value is 15% or less. When the minimum collapse rate is 5% or less, the first collapse rate is less than 15%. Therefore, when the compounding ratio is the optimum compounding ratio, the collapse rate is 5% or less. When the compounding ratio is the first compounding ratio, the collapse rate is less than 15%. Therefore, when the compounding ratio is within the range from the optimum compounding ratio to the first compounding ratio, the collapse rate is low. When the compounding ratio is in the range from the optimum compounding ratio to the first compounding ratio, the pattern on the substrate is suitably protected. Therefore, it is easier to appropriately dry the substrate.

In the substrate treating method described above, the minimum collapse rate is preferably 1% or less.

When the minimum collapse rate is 1% or less, the first reference value is 6% or less. Therefore, when the compounding ratio is within the first range, the collapse rate is 6% or less. Therefore, when the compounding ratio is within the first range, the collapse rate is even lower. When the compounding ratio is within the first range, the pattern on the substrate is more suitably protected. Therefore, it is further easier to appropriately dry the substrate.

When the minimum collapse rate is 1% or less, the second reference value is 11% or less. When the minimum collapse rate is 1% or less, the first collapse rate is less than 11%. Therefore, when the compounding ratio is the optimum compounding ratio, the collapse rate is 1% or less. When the compounding ratio is the first compounding ratio, the collapse rate is less than 11%. Therefore, when the compounding ratio is within the range from the optimum compounding ratio to the first compounding ratio, the collapse rate is even lower. When the compounding ratio is within the range from the optimum compounding ratio to the first compounding ratio, the pattern on the substrate is more suitably protected. Therefore, it is further easier to appropriately dry the substrate.

In the substrate treating method described above, it is preferable that a ratio of a volume of the sublimable substance for producing the treatment liquid to a volume of the solvent for producing the treatment liquid is defined as a compounding ratio (vol %), a probability that the pattern on the substrate collapses when the substrate is treated in the treatment liquid supply step, the solidified film forming step, and the sublimation step is defined as a collapse rate (%), and a range of the compounding ratio when the collapse rate is 20 (%) or less is defined as a second range, and the second range has a width of 10 or more.

When the compounding ratio is within the second range, the collapse rate is 20 (%) or less. Therefore, when the compounding ratio is within the second range, the collapse rate is low. When the compounding ratio is within the second range, the pattern on the substrate is suitably protected. When the compounding ratio is within the second range, the substrate is appropriately treated.

The second range has a width of 10 or more. The second range has a width of 10 vol % or more. That is, the width of the second range is wide. Here, the compounding ratio is one of the conditions of the treatment liquid. The second range corresponds to the range of conditions of the treatment liquid. The second range corresponds to the process window for the treatment liquid. Therefore, the conditions of the treatment liquid are lax. The process window for the treatment liquid is wide. Therefore, it is easier to properly dry the substrate.

“A range of the compounding ratio when the collapse rate is 20 (%) or less” can also be said to be a range of the compounding ratio in which a collapse rate of 20 (%) or less is obtained.

In the substrate treating method described above, it is preferable that when the maximum height of the solidified film is about 3.5 times the height of the pattern, the collapse rate is 20% or less. The maximum height of the solidified film depends on the compounding ratio. When the maximum height of the solidified film is about 3.5 times the height of the pattern, the substrate is appropriately treated. This indicates that the process window for the treatment liquid is even wider. As described above, the process window for the treatment liquid is even wider. Therefore, it is even easier to appropriately dry the substrate.

In the substrate treating method described above, it is preferable that when the maximum height of the solidified film is about 4.0 times the height of the pattern, the collapse rate is 20% or less. The maximum height of the solidified film depends on the compounding ratio. When the maximum height of the solidified film is about 4.0 times the height of the pattern, the substrate is appropriately treated. This indicates that the process window for the treatment liquid is even wider. As described above, the process window for the treatment liquid is even wider. Therefore, it is even easier to appropriately dry the substrate.

The present invention is a substrate treating apparatus including a substrate holder that holds a substrate; and a treatment liquid supply unit that supplies a treatment liquid containing a sublimable substance and a solvent to the substrate held by the substrate holder; and the sublimable substance having a vapor pressure at normal temperatures of 0.1 Pa or more and 1.0 Pa or less.

The substrate treating apparatus includes the substrate holder and the treatment liquid supply unit. The substrate holder holds the substrate. The treatment liquid supply unit supplies the treatment liquid to the substrate held by the substrate holder. The treatment liquid contains a sublimable substance and a solvent. Therefore, when the treatment liquid is supplied to the substrate, the solvent is evaporated from the treatment liquid on the substrate. The solidified film is formed on the substrate by evaporation of the solvent. The solidified film contains the sublimable substance. Therefore, the solidified film sublimates. The substrate is dried by sublimation of the solidified film.

Here, the sublimable substance has a vapor pressure at normal temperatures of 0.1 Pa or more and 1.0 Pa or less. Therefore, the conditions of the treatment liquid for appropriately treating the substrate are laxer. In other words, the process window for the treatment liquid is wider. For example, the process window of the treatment liquid containing the sublimable substance having a vapor pressure of 0.1 Pa or more and 1.0 Pa or less at normal temperatures is wider than the process window of the treatment liquid containing the sublimable substance having a vapor pressure of more than 1.0 Pa at normal temperatures. Therefore, it is easier to appropriately dry the substrate.

As described above, according to this substrate treating apparatus, the substrate is appropriately dried.

In the substrate treating apparatus described above, the sublimable substance preferably has a solubility in the solvent of 150 vol % or more at normal temperatures. The conditions of the treatment liquid for appropriately treating the substrate are even laxer. In other words, the process window for the treatment liquid is further wider. For example, the process window of the treatment liquid having a solubility of the sublimable substance in the solvent of 150 vol % or more at normal temperatures is further wider than the process window of the treatment liquid having a solubility of the sublimable substance in the solvent of less than 150 vol % at normal temperatures. Therefore, it is further easier to appropriately dry the substrate.

The present invention is a treatment liquid used for drying a substrate on which a pattern is formed, the treatment liquid containing: a sublimable substance; and a solvent; and the sublimable substance having a vapor pressure at normal temperatures of 0.1 Pa or more and 1.0 Pa or less.

The treatment liquid is used for drying the substrate on which the pattern is formed. Specifically, the treatment liquid is the dry-assisting liquid. The treatment liquid contains a sublimable substance and a solvent.

Here, the sublimable substance has a vapor pressure at normal temperatures of 0.1 Pa or more and 1.0 Pa or less. Therefore, the conditions of the treatment liquid for appropriately treating the substrate are laxer. In other words, the process window for the treatment liquid is wider. For example, the process window of the treatment liquid containing the sublimable substance having a vapor pressure of 0.1 Pa or more and 1.0 Pa or less at normal temperatures is wider than the process window of the treatment liquid containing the sublimable substance having a vapor pressure of more than 1.0 Pa at normal temperatures. Therefore, by using the treatment liquid, it is easier to appropriately dry the substrate. Specifically, by using the treatment liquid, it is easier to dry the substrate while suitably protecting the pattern on the substrate. By using the treatment liquid, it is easier to prevent pattern collapse in the dry treatment of the substrate. As described above, the treatment liquid is useful for drying the substrate.

As described above, the substrate is appropriately dried using the treatment liquid.

In the treatment liquid described above, the sublimable substance preferably has a solubility in the solvent of 150 vol % or more at normal temperatures. The conditions of the treatment liquid for appropriately treating the substrate are even laxer. In other words, the process window for the treatment liquid is further wider. For example, the process window of the treatment liquid having a solubility of the sublimable substance in the solvent of 150 vol % or more at normal temperatures is further wider than the process window of the treatment liquid having a solubility of the sublimable substance in the solvent of less than 150 vol % at normal temperatures. Therefore, it is further easier to appropriately dry the substrate using the treatment liquid. Therefore, the substrate is more appropriately dried using the treatment liquid.

In the treatment liquid described above, the sublimable substance is preferably 4-tert-butylphenol. 4-tert-butylphenol has a vapor pressure at normal temperatures of 0.1 Pa or more and 1.0 Pa or less. When the sublimable substance is 4-tert-butylphenol, it is suitably satisfied that the sublimable substance has a vapor pressure at normal temperatures of 0.1 Pa or more and 1.0 Pa or less. Therefore, the conditions of the treatment liquid for appropriately treating the substrate are laxer. Therefore, it is easier to appropriately dry the substrate using the treatment liquid.

In the treatment liquid described above, the sublimable substance is preferably acetophenone oxime. Acetophenone oxime has a vapor pressure at normal temperatures of 0.1 Pa or more and 1.0 Pa or less. When the sublimable substance is acetophenone oxime, it is suitably satisfied that the sublimable substance has a vapor pressure at normal temperatures of 0.1 Pa or more and 1.0 Pa or less. Therefore, the conditions of the treatment liquid for appropriately treating the substrate are laxer. Therefore, it is easier to appropriately dry the substrate using the treatment liquid.

In the treatment liquid described above, the solvent is preferably isopropyl alcohol. 4-tert-butylphenol has a solubility in isopropyl alcohol of 150 vol % or more at normal temperatures. Acetophenone oxime has a solubility in isopropyl alcohol of 150 vol % or more at normal temperatures. When the solvent is isopropyl alcohol, it is easy to control the solubility of the sublimable substance in the solvent to 150 vol % or more at normal temperatures. Therefore, the conditions of the treatment liquid for appropriately treating the substrate are even laxer. Therefore, it is further easier to appropriately dry the substrate using the treatment liquid.

### Advantageous Effects of Invention

According to the substrate treating method, the substrate treating apparatus, and the treatment liquid of the present invention, the substrate is appropriately dried.

### BRIEF DESCRIPTION OF DRAWINGS

FIG. 1 is a view schematically showing a part of a substrate.

FIG. 2 is a plan view of an interior of a substrate treating apparatus according to an embodiment.

FIG. 3 is a control block diagram of the substrate treating apparatus.

FIG. 4 is a diagram showing a construction of a treating unit and a first supply source.

FIG. 5 is a flow chart showing procedures of a substrate treating method according to the embodiment.

FIG. 6 is a view schematically showing a substrate in a treatment liquid supply step.

FIG. 7 is a view schematically showing the substrate in a solidified film forming step.

FIG. 8 is a view schematically showing the substrate in the solidified film forming step.

FIG. 9 is a view schematically showing the substrate in a sublimation step.

FIG. 10 is a view schematically showing the substrate in the sublimation step.

FIG. 11 is a table showing collapse rates of substrates treated in Example Group 1.

FIG. 12 is a table showing collapse rates of substrates treated in Example Group 2.

FIG. 13 is a table showing collapse rates of substrates treated in Comparative Example Group 1.

FIG. 14 is a table showing collapse rates of substrates treated in Comparative Example Group 2.

FIG. 15 is a graph showing relationships between compounding ratios and collapse rates in Example Groups 1 and 2 and Comparative Example Groups 1 and 2.

FIG. 16 is a graph showing relationships between compounding ratios and maximum heights of solidified films in Example Groups 1 and 2 and Comparative Example Groups 1 and 2.

FIG. 17 is a table obtained by analyzing the collapse rates of the substrates treated in Example Groups 1 and 2 and Comparative Example Groups 1 and 2.

FIGS. 18(a), 18(b), and 18(c) are views schematically showing the substrate in the solidified film forming step of Comparative Example Groups 1 and 2, respectively.

FIGS. 19(a) and 19(b) are views schematically showing the substrate in the solidified film forming step of Comparative Example Groups 1 and 2, respectively.

FIGS. 20(a) and 20(b) are views schematically showing the substrate in the solidified film forming step of Example Groups 1 and 2, respectively.

FIG. 21 is a diagram showing a construction of a treating unit and a first supply source according to a modified embodiment.

### DESCRIPTION OF EMBODIMENTS

The following describes a substrate treating method, a substrate treating apparatus, and a treatment liquid of the present invention with reference to the drawings.

### 1. Substrate

The substrate W is, for example, a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, a solar cell substrate. The substrate W has a thin and flat plate shape. The substrate W has a substantially circular shape in plan view.

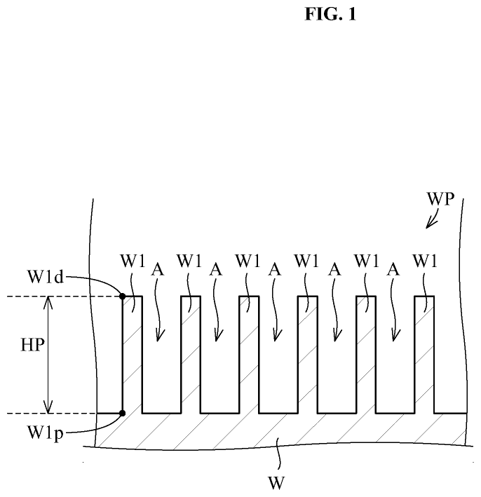

FIG. 1 is a diagram schematically showing a part of the substrate W. The substrate W has a pattern WP. The pattern WP is formed on the surface of the substrate W.

The pattern WP has, for example, an uneven shape. The pattern WP includes, for example, a plurality of projections W1. The projections W1 are part of the substrate W. The projections W1 are a structure. The projections W1 are each formed with, for example, at least one of a silicon oxide (SiO2) film, a silicon nitride (SiN) film, and a polysilicon film. The projections W1 project upward from the surface of the substrate W, for example. The plurality of projections W1 are separated from each other. The plurality of projections W1 are arranged in the horizontal direction, for example. The projection W1 defines a recess A. The recess A is a space. The recess A is located between two adjacent projections W1. The recess A is laterally adjacent to the projection W1. The recess A is opened upward, for example.

The projection W1 has height HP. Specifically, the projection W1 has a base end W1p and a tip W1d. The base end W1p corresponds to a proximal end of the projection W1. The tip W1d corresponds to a distal end of the projection W1. The height HP corresponds to a distance between the base end W1p and the tip W1d. In this specification, the height HP is appropriately referred to as the height HP of the pattern WP.

### 2. Treatment Liquid (Dry-Assisting Liquid)

In this specification, the treatment liquid used for drying the substrate W is simply referred to as a “treatment liquid”. The treatment liquid has a function of assisting drying of the substrate W. The treatment liquid can be rephrased as the dry-assisting liquid.

The treatment liquid contains a sublimable substance. The sublimable substance has sublimability. “Sublimability” means a property that a single substance, a compound or a mixture changes its phase from a solid phase to a gas phase or from a gas phase to a solid phase without passing through a liquid phase.

The sublimable substance has a vapor pressure of 0.1 Pa or more and 1.0 Pa or less at normal temperatures. Here, the normal temperatures include a room temperature. The normal temperatures fall within a temperature range of 5° C. or more and 35° C. or less, for example. The normal temperatures fall within a temperature range of 10° C. or more and 30° C. or less, for example. In this specification, the value of vapor pressure is indicated as absolute pressure relative to absolute vacuum.

The sublimable substance contains, for example, either 4-tert-butylphenol or acetophenone oxime. For example, the sublimable substance contains, for example, only 4-tert-butylphenol. For example, the sublimable substance contains, for example, only acetophenone oxime.

4-tert-butylphenol is represented by the following chemical formula (1).

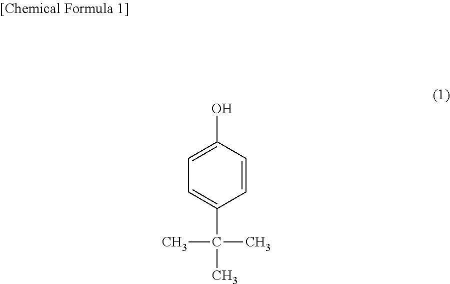

Acetophenone oxime is represented by the following chemical formula (2).

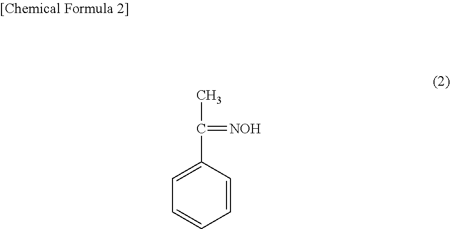

4-tert-butylphenol has a vapor pressure at normal temperatures of 0.1 Pa or more and 1.0 Pa or less. Specifically, 4-tert-butylphenol has a vapor pressure at 25° C. of 0.54 Pa. Therefore, when the sublimable substance is 4-tert-butylphenol, it is suitably satisfied that the sublimable substance has a vapor pressure at normal temperatures of 0.1 Pa or more and 1.0 Pa or less. Acetophenone oxime also has a vapor pressure at normal temperatures of 0.1 Pa or more and 1.0 Pa or less. Specifically, acetophenone oxime has a vapor pressure at 25° C. of 0.27 Pa. Therefore, when the sublimable substance is acetophenone oxime, it is suitably satisfied that the sublimable substance has a vapor pressure at normal temperatures of 0.1 Pa or more and 1.0 Pa or less.

The vapor pressure of the sublimable substance at normal temperatures is not lower than 0.1 Pa. The sublimable substance does not contain a compound having a vapor pressure lower than 0.1 Pa at normal temperatures.

The vapor pressure of the sublimable substance at normal temperatures is not higher than 1.0 Pa. The sublimable substance does not contain a compound having a vapor pressure higher than 1.0 Pa at normal temperatures.

For example, cyclohexanone oxime has a vapor pressure higher than 1.0 Pa at normal temperatures. Specifically, cyclohexanone oxime has a vapor pressure at 25° C. of 1.45 Pa. Therefore, the sublimable substance does not contain cyclohexanone oxime. For example, pinacolone oxime has a vapor pressure higher than 1.0 Pa at normal temperatures. Specifically, pinacolone oxime has a vapor pressure at 25° C. of 35.3 Pa. Therefore, the sublimable substance does not contain pinacolone oxime.

The treatment liquid contains a solvent. The solvent dissolves the sublimable substance. The sublimable substance in the treatment liquid is dissolved in the solvent. That is, the treatment liquid contains the solvent and the sublimable substance dissolved in the solvent. The sublimable substance corresponds to a solute of the treatment liquid.

The ability of the solvent to dissolve the sublimable substance is preferably high.

The ability of the solvent to dissolve the sublimable substance is indicated, for example, by the solubility of the sublimable substance in the solvent. Hereinafter, the solubility of the sublimable substance in the solvent is appropriately referred to as solubility Rm. The solubility Rm is a limit amount of sublimable substance that is soluble in a certain amount of solvent. As the solubility Rm increases, the ability of the solvent to dissolve the sublimable substance increases. Therefore, the solubility Rm is preferably high.

In general, the solubility Rm varies with temperature. The treatment liquid is used at normal temperatures. Therefore, the solubility Rm is preferably high at normal temperatures. The solubility Rm is preferably 150 vol % or more at normal temperatures.

For example, when the maximum volume of the sublimable substance soluble in the solvent of volume Q2c is Q1m, the solubility Rm is a ratio of the maximum volume Q1m to the volume Q2c. Specifically, the solubility Rm is defined by the following formula.

$$Solubility Rm = ( Maximum volume Q 1 m ) / ( Volume Q 2 c ) * 100 ( vol \% )$$

When the solvent of volume Q2c dissolves the sublimable substance of maximum volume Q1m, the treatment liquid is saturated.

Furthermore, the solvent has a relatively high vapor pressure at normal temperatures. For example, the vapor pressure of the solvent at normal temperatures is preferably higher than the vapor pressure of the sublimable substance at normal temperatures. For example, the vapor pressure of the solvent at normal temperatures is preferably higher than 1.0 Pa.

The solvent is, for example, an organic solvent. The solvent is, for example, an alcohol.

The solvent contains, for example, isopropyl alcohol (IPA). The solvent contains, for example, only isopropyl alcohol (IPA).

When the solvent is isopropyl alcohol and the sublimable substance is 4-tert-butylphenol, the solubility Rm is 150 vol % or more at normal temperatures. Specifically, when the solvent is isopropyl alcohol and the sublimable substance is 4-tert-butylphenol, the solubility Rm is 171 vol % at 25° C. Therefore, when the solvent is isopropyl alcohol and the sublimable substance is 4-tert-butylphenol, it is suitably satisfied that the solubility Rm is 150 vol % or more at normal temperatures.

When the solvent is isopropyl alcohol and the sublimable substance is acetophenone oxime, the solubility Rm is 150 vol % or more at normal temperatures. Specifically, when the solvent is isopropyl alcohol and the sublimable substance is acetophenone oxime, the solubility Rm is 186 vol % at 25° C. Therefore, when the solvent is isopropyl alcohol and the sublimable substance is acetophenone oxime, it is suitably satisfied that the solubility Rm is 150 vol % or more at normal temperatures. Furthermore, the vapor pressure of isopropyl alcohol at normal temperatures is higher than the vapor pressure of 4-tert-butylphenol at normal temperatures. The vapor pressure of isopropyl alcohol at normal temperatures is higher than the vapor pressure of acetophenone oxime at normal temperatures.

The treatment liquid consists of, for example, only the sublimable substance and the solvent. The treatment liquid consists of, for example, only 4-tert-butylphenol and isopropyl alcohol. The treatment liquid consists of, for example, only acetophenone oxime and isopropyl alcohol.

### 3. Outline of Substrate Treating Apparatus

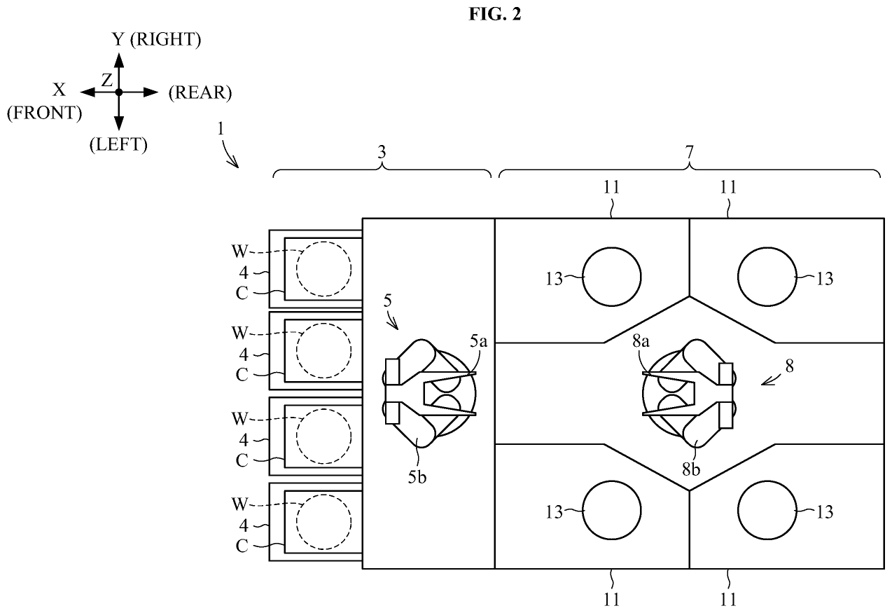

FIG. 2 is a plan view of an interior of a substrate treating apparatus 1 according to the embodiment. The substrate treating apparatus 1 performs treatment on the substrate W. The treatment in the substrate treating apparatus 1 includes a dry treatment.

The substrate treating apparatus 1 includes an indexer 3 and a treating block 7. The treating block 7 is connected to the indexer 3. The indexer 3 supplies the substrate W to the treating block 7. The treating block 7 performs a treatment on the substrate W. The indexer 3 collects the substrate W from the treating block 7.

In this specification, the direction in which the indexer 3 and the treating block 7 are arranged is referred to as a “front-rear direction X” for convenience. The front-rear direction X is horizontal. One direction of the front-rear direction X from the treating block 7 to the indexer 3 is referred to as a “forward direction”. The direction opposite to the forward direction is referred to as a “rearward direction”. A horizontal direction orthogonal to the front-rear direction X is referred to as a “transverse direction Y”. Moreover, one direction of the transverse direction Y is referred to as a “rightward direction”, as appropriate. The direction opposite to the rightward direction is referred to as a “leftward direction”. The perpendicular direction relative to the horizontal direction is referred to as a “vertical direction Z”. For reference, the drawings show front, rear, right, left, up, and down, as appropriate.

The indexer 3 includes a plurality of (e.g., four) carrier platforms 4. The carrier platforms 4 each include one carrier C placed thereon. The carrier C accommodates a plurality of substrates W. The carrier C is, for example, a front opening unified pod (FOUP), a standard mechanical interface (SMIF), or an open cassette (OC).

The indexer 3 includes a transport mechanism 5. The transport mechanism 5 is arranged rearward of the carrier platforms 4. The transport mechanism 5 transports the substrate W. The transport mechanism 5 is accessible to the carriers C placed on the carrier platforms 4, respectively. The transport mechanism 5 includes a hand 5a and a hand driving unit 5b. The hand 5a supports the substrate W. The hand driving unit 5b is coupled to the hand 5a. The hand driving unit 5b moves the hand 5a. The hand driving unit 5b moves the hand 5a in the front-rear direction X, transverse direction Y, and vertical direction Z, for example. The hand driving unit 5b rotates the hand 5a in a horizontal plane, for example.

The treating block 7 includes a transport mechanism 8. The transport mechanism 8 transports the substrate W. The transport mechanism 5 and the transport mechanism 8 are configured to transfer the substrate W to each other. The transport mechanism 8 includes a hand 8a and a hand driving unit 8b. The hand 8a supports the substrate W. The hand driving unit 8b is coupled to the hand 8a. The hand driving unit 8b moves the hand 8a. The hand driving unit 8b moves the hand 8a in the front-rear direction X, transverse direction Y, and vertical direction Z, for example. The hand driving unit 8b rotates the hand 8a in a horizontal plane, for example.

The treating block 7 includes a plurality of treating units 11. The treating units 11 are each arranged laterally of the transport mechanism 8. The treating units 11 each perform a treatment on the substrate W individually.

The treating unit 11 includes a substrate holder 13. The substrate holder 13 holds the substrate W.

The transport mechanism 8 is accessible to the treating units 11 individually. The transport mechanism 8 can deliver the substrate W to the substrate holder 13. The transport mechanism 8 can take the substrate W from the substrate holder 13.

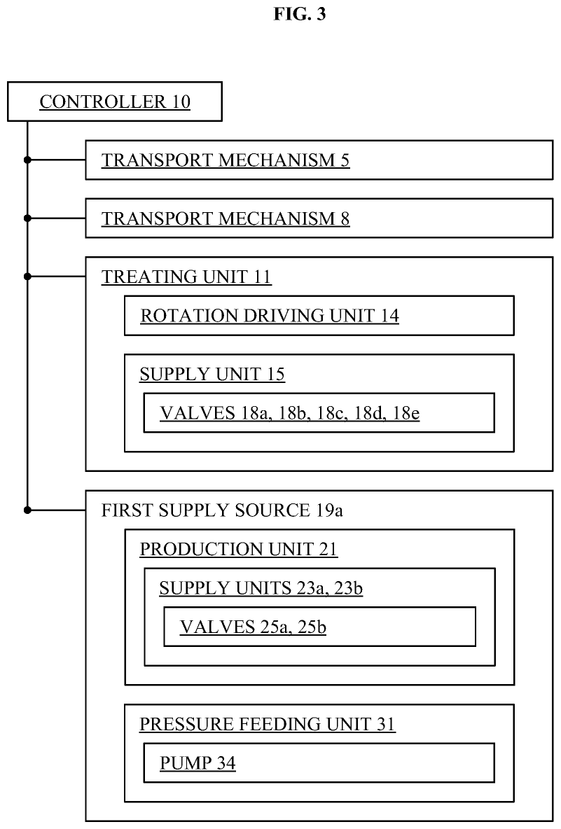

FIG. 3 is a control block diagram of the substrate treating apparatus 1. The substrate treating apparatus 1 includes a controller 10. The controller 10 can communicate with the transport mechanisms 5, 8 and the treating units 11. The controller 10 controls the transport mechanisms 5, 8 and the treating units 11.

The controller 10 is implemented by a central processing unit (CPU) that performs various processes, a random access memory (RAM) as a workspace of arithmetic processing, and a storage medium such as a fixed disk. The controller 10 contains various types of information stored in the storage medium in advance. The information stored in the controller 10 includes transportation condition information for controlling the transport mechanisms 5, 8, for example. The information stored in the controller 10 includes processing condition information for controlling the treating units 11, for example. The processing condition information is also called processing recipes.

The following simply describes one example of operation of the substrate treating apparatus 1.

The indexer 3 supplies the substrate W to the treating block 7. Specifically, the transport mechanism 5 delivers the substrate W from the carriers C to the transport mechanism 8 of the treating block 7.

The transport mechanism 8 distributes the substrate W to the treating unit 11. Specifically, the transport mechanism 8 transports the substrate W from the transport mechanism 5 to the substrate holders 13 of the treating units 11.

The treating unit 11 performs treatment on the substrate W held by the substrate holder 13. The treating unit 11 performs a dry treatment, for example, on the substrate W.

After the treating unit 11 performs treatment on the substrate W, the transport mechanism 8 collects the substrate W from the treating units 11. Specifically, the transport mechanism 8 receives the substrate W from the substrate holders 13. Then, the transport mechanism 8 delivers the substrate W to the transport mechanism 5.

The indexer 3 collects the substrate W from the treating block 7. Specifically, the transport mechanism 5 transports the substrate W from the transport mechanism 8 to the carriers C.

### 4. Construction of Treating Unit 11

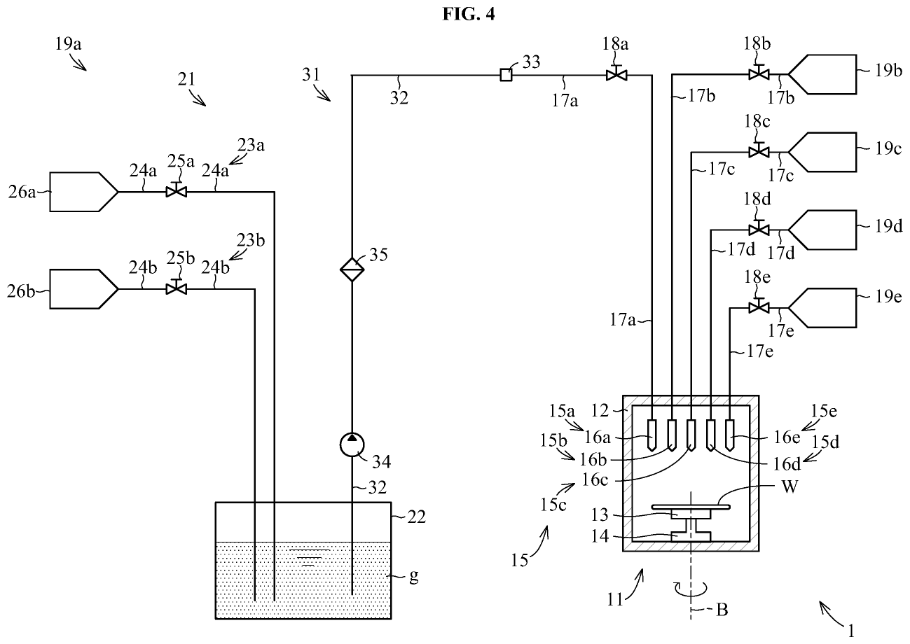

FIG. 4 is a diagram showing a construction of the treating unit 11. The treating units 11 each have the same construction. The treating unit 11 is classified as a single-wafer processing unit. That is, the treating units 11 each perform a treatment on only one substrate W at one time.

The treating unit 11 includes a casing 12. The casing 12 has a substantial box shape. The substrate W is treated within the casing 12.

The interior of the casing 12 is kept at normal temperatures. Accordingly, the substrate W is treated under an environment of normal temperatures.

The interior of the casing 12 is kept at normal pressure. Accordingly, the substrate W is treated under an environment of normal pressure.

Here, the normal pressure includes standard atmospheric pressure (1 atm, 101325 Pa). The normal pressure falls within a pressure range of 0.7 to 1.3 atm, for example. In this specification, the value of pressure is indicated as absolute pressure relative to absolute vacuum.

The substrate holder 13 described above is installed in the interior of the casing 12. The substrate holder 13 holds one substrate W. The substrate holder 13 holds the substrate W in a substantially horizontal posture.

The substrate holder 13 is located below the substrate W held by the substrate holder 13. The substrate holder 13 is in contact with at least one of a lower surface of the substrate W and a peripheral edge of the substrate W. The lower surface of the substrate W is also called a back side of the substrate W. The substrate holder 13 is not in contact with an upper surface of the substrate W.

The treating units 11 each include a rotation driving unit 14. At least a part of the rotation driving unit 14 is installed in the interior of the casing 12. The rotation driving unit 14 is connected to the substrate holder 13. The rotation driving unit 14 rotates the substrate holder 13. The substrate W held by the substrate holder 13 rotates integrally with the substrate holder 13. The substrate W held by the substrate holder 13 rotates around a rotation axis B. The rotation axis B passes through the center of the substrate W and extends in the vertical direction Z, for example.

The treating unit 11 includes a supply unit 15. The supply unit 15 supplies a liquid or gas to the substrate W held by the substrate holder 13. Specifically, the supply unit 15 supplies liquid or gas onto the upper surface of the substrate W held by the substrate holder 13.

The supply unit 15 includes a first supply unit 15a, a second supply unit 15b, a third supply unit 15c, a fourth supply unit 15d, and a fifth supply unit 15e. The first supply unit 15a supplies the treatment liquid. The second supply unit 15b supplies a chemical liquid. The third supply unit 15c supplies a rinse liquid. The fourth supply unit 15d supplies a replacement solution. The fifth supply unit 15e supplies a dry gas.

The first supply unit 15a is an example of the treatment liquid supply unit in the present invention.

As described above, the interior of the casing 12 is at normal temperatures and normal pressure. Accordingly, the treatment liquid is used under an environment of normal temperatures. The treatment liquid is used under an environment of normal pressure.

The chemical liquid supplied by the second supply unit 15b is, for example, an etchant. The etchant includes, for example, at least either hydrofluoric acid (HF) or buffered hydrofluoric acid (BHF).

The rinse liquid supplied by the third supply unit 15c is, for example, deionized water (DIW).

The replacement solution supplied by the fourth supply unit 15d is, for example, an organic solvent. The replacement solution is, for example, isopropyl alcohol (IPA).

The dry gas supplied by the fifth supply unit 15e preferably has a dew point lower than normal temperatures. The dry gas is, for example, at least one of air and inert gas. The air is, for example, compressed air. The inert gas is, for example, nitrogen gas.

The first supply unit 15a includes a nozzle 16a. Likewise, the second to fifth supply units 15b to 15e include nozzles 16b to 16e, respectively. Each of the nozzles 16a to 16e is installed in the interior of the casing 12. The nozzle 16a dispenses the treatment liquid. The nozzle 16b dispenses the chemical liquid. The nozzle 16c dispenses the rinse liquid. The nozzle 16d dispenses the replacement solution. The nozzle 16e dispenses the dry gas.

The first supply unit 15a includes a pipe 17a and a valve 18a. The pipe 17a is connected to the nozzle 16a. The valve 18a is provided on the pipe 17a. When the valve 18a opens, the nozzle 16a dispenses the treatment liquid. When the valve 18a closes, the nozzle 16a does not dispense the treatment liquid. Likewise, the second to fifth supply units 15b to 15e include pipes 17b to 17e and valves 18b to 18e, respectively. The pipes 17b to 17e are connected to the nozzles 16b to 16e, respectively. The valves 18b to 18e are provided on the pipes 17b to 17e, respectively. The valves 18b to 18e control dispensing of the chemical liquid, the rinse liquid, the replacement solution, and the dry gas, respectively.

At least part of the pipe 17a may be provided externally of the casing 12. The same arrangement of the pipe 17a is applicable to arrangement of the pipes 17b to 17e. The valve 18a may be provided externally of the casing 12. The same arrangement of the valve 18a is applicable to arrangement of the valves 18b to 18e.

The substrate treating apparatus 1 includes a first supply source 19a. The first supply source 19a is connected to the first supply unit 15a. The first supply source 19a is in fluid communication with the first supply unit 15a. The first supply source 19a is connected to, for example, the pipe 17a. The first supply source 19a feeds the treatment liquid to the first supply unit 15a.

The second supply unit 15b is connected to the second supply source 19b. The second supply unit 15b is in fluid communication with the second supply source 19b. The second supply source 19b is connected to, for example, the pipe 17b. The second supply source 19b feeds the chemical liquid to the second supply unit 15b. Likewise, the third to fifth supply units 15c to 15e are connected to the third to fifth supply sources 19c to 19e, respectively. The third to fifth supply units 15c to 15e are in fluid communication with the third to fifth supply sources 19c to 19e, respectively. For example, the third to fifth supply sources 19c to 19e are connected to the pipes 17c to 17e, respectively. The third supply source 19c feeds the rinse liquid to the third supply unit 15c. The fourth supply source 19d feeds the replacement solution to the fourth supply unit 15d. The fifth supply source 19e feeds the dry gas to the fifth supply unit 15e.

The first supply source 19a is provided externally of the casing 12. Likewise, each of the second to fifth supply sources 19b to 19e is provided externally of the casing 12.

The first supply source 19a may supply the treatment liquid to the plurality of treating units 11. Alternatively, the first supply source 19a may supply the treatment liquid to only one treating unit 11. The same applies to the second to fifth supply sources 19b to 19e.

The second supply source 19b may be an element of the substrate treating apparatus 1. For example, the second supply source 19b may be a chemical tank included in the substrate treating apparatus 1. Alternatively, the second supply source 19b may not be an element of the substrate treating apparatus 1. For example, the second supply source 19b may be a utility equipment located externally of the substrate treating apparatus 1. Likewise, each of the third to fifth supply sources 19c to 19e may be an element of the substrate treating apparatus 1. Alternatively, each of the third to fifth supply sources 19c to 19e may not be an element of the substrate treating apparatus 1.

The treating unit 11 may further include a cup, not shown. The cup is located inside of the casing 12. The cup is arranged around the substrate holder 13. The cup receives the liquid scattered from the substrate W held by the substrate holder 13. Reference is made to FIG. 3. The controller 10 controls the rotation driving unit 14. The controller 10 controls the supply unit 15. The controller 10 controls the valves 18a to 18e.

### 5. Construction of First Supply Source 19a

Reference is made to FIG. 4. The first supply source 19a further produces a treatment liquid.

A construction example of the first supply source 19a will be exemplified. The first supply source 19a is divided into a production unit 21 and a pressure feeding unit 31. The production unit 21 produces the treatment liquid. The pressure feeding unit 31 feeds the treatment liquid to the first supply unit 15a.

The production unit 21 includes a tank 22 and supply units 23a and 23b. The supply unit 23a supplies the sublimable substance to the tank 22. The supply unit 23b supplies the solvent to the tank 22. The sublimable substance and the solvent are mixed in the tank 22. The sublimable substance and the solvent become the treatment liquid g in the tank 22.

The tank 22 is installed under an environment of normal temperatures. The tank 22 is installed under an environment of normal pressure. Accordingly, the treatment liquid g is produced under an environment of normal temperatures. The treatment liquid g is produced under an environment of normal pressure.

Further, the production unit 21 stores the treatment liquid g. Specifically, the treatment liquid g is stored in the tank 22. The treatment liquid g is stored under an environment of normal temperatures. The treatment liquid g is stored under an environment of normal pressure.

The supply unit 23a includes, for example, a pipe 24a and a valve 25a. The pipe 24a is connected to the tank 22. The pipe 24a is in fluid communication with the tank 22. The valve 25a is provided on the pipe 24a. When the valve 25a opens, the supply unit 23a supplies the sublimable substance to the tank 22. When the valve 25a closes, the supply unit 23a does not supply the sublimable substance to the tank 22. Likewise, the supply unit 23b includes a pipe 24b and a valve 25b. The pipe 24b is connected to the tank 22. The pipe 24b is in fluid communication with the tank 22. The valve 25b is provided on the pipe 24b. The valve 25b controls the supply of the solvent to the tank 22.

Furthermore, the valve 25a adjusts the amount of sublimable substance supplied to the tank 22. The valve 25b adjusts the amount of solvent supplied to the tank 22.

Each of the valves 25a and 25b may include, for example, a flow rate control valve. Each of the valves 25a and 25b may include, for example, a flow rate control valve and an on-off valve.

The supply unit 23a is connected to a supply source 26a. The supply unit 23a is in fluid communication with the supply source 26a. For example, the supply source 26a is connected to the pipe 24a. The supply source 26a feeds the sublimable substance to the supply unit 23a. Likewise, the supply unit 23b is connected to the supply source 26b. The supply unit 23b is in fluid communication with the supply source 26b. For example, the supply source 26b is connected to the pipe 24b. The supply source 26b feeds the solvent to the supply unit 23b.

Here, the volume of the sublimable substance for producing the treatment liquid g is defined as volume Q1g. More particularly, the volume Q1g is the volume of the sublimable substance used to produce the treatment liquid g. The volume of the solvent for producing the treatment liquid g is defined as volume Q2g. More particularly, the volume Q2g is the volume of the solvent used to produce the treatment liquid g. The ratio of the volume Q2g to the volume Q1g is referred to as compounding ratio R of the treatment liquid g or simply as compounding ratio R. Specifically, the compounding ratio R is defined by the following formula.

$$Compounding ratio R = ( Volume Q 1 g ) / ( Volume Q 2 g ) * 100 ( Vol \% )$$

The compounding ratio R is limited to equal to or less than the above-described solubility Rm. The solubility Rm corresponds to the upper limit value of the compounding ratio R.

The compounding ratio R substantially determines concentration V of the sublimable substance in the treatment liquid g. Hereinafter, the concentration V of the sublimable substance in the treatment liquid g is referred to as the concentration V of the treatment liquid g or simply as the concentration V. Strictly speaking, the compounding ratio R substantially determines initial concentration V0. The initial concentration V0 is, for example, the concentration V of the treatment liquid g when the treatment liquid g is produced. The initial concentration V0 is, for example, the concentration V of the treatment liquid g when the treatment liquid g is stored. The initial concentration V0 is the concentration V of the treatment liquid g before the treatment liquid g is supplied to the substrate W.

The volume Q1g is adjusted by the valve 25a. The volume Q2g is adjusted by the valve 25b. The compounding ratio R is adjusted by the valves 25a. 25b. The initial concentration V0 is substantially adjusted by the valves 25a. 25b.

The pressure feeding unit 31 includes a pipe 32 and a joint 33. The pipe 32 is connected to the tank 22. The pipe 32 is in fluid communication with the tank 22. The joint 33 is connected to the pipe 32. The joint 33 is also connected to the pipe 17a. The pipe 32 is connected to the pipe 17a by the joint 33. The pipe 32 is in fluid communication with the pipe 17a by the joint 33. Accordingly, the tank 22 is connected to the first supply unit 15a via the pipe 32 and the joint 33. The tank 22 is in fluid communication with the first supply unit 15a via the pipe 32 and the joint 33. The tank 22 is connected to the nozzle 16a. The tank 22 is in fluid communication with the nozzle 16a.

The pressure feeding unit 31 further includes a pump 34 and a filter 35. The pump 34 is provided on the pipe 32. When the pump 34 actuates, the pump 34 feeds the treatment liquid g from the tank 22 to the first supply unit 15a. When the pump 34 actuates, the pump 34 pressure-feeds the treatment liquid g from the tank 22 to the first supply unit 15a. When the pump 34 stops actuation, the pump 34 does not feed the treatment liquid g from the tank 22 to the first supply unit 15a. When the pump 34 stops actuation, the pump 34 does not pressure-feed the treatment liquid g from the tank 22 to the first supply unit 15a. The filter 35 is provided on the pipe 32. The treatment liquid g passes through the filter 35. The filter 35 filters the treatment liquid g. The filter 35 removes foreign substances from the treatment liquid g.

Reference is made to FIG. 3. The controller 10 can communicate with the first supply source 19a. The controller 10 controls the first supply source 19a. The controller 10 controls the production unit 21. The controller 10 controls the supply units 23a and 23b. The controller 10 controls the valves 25a and 25b. The controller 10 controls the pressure feeding unit 31. The controller 10 controls the pump 34.

The controller 10 has treatment liquid condition information for controlling the first supply source 19a. The treatment liquid condition information includes information on the condition of the treatment liquid g. The conditions of the treatment liquid g include, for example, the compounding ratio R. The conditions of the treatment liquid g relate to, for example, the compounding ratio R. The conditions of the treatment liquid g may have a certain range, for example. The range of conditions of the treatment liquid g includes, for example, the range of the compounding ratio R. The treatment liquid condition information includes, for example, a target for the compounding ratio R. The treatment liquid condition information defines, for example, the target for the compounding ratio R. The target for the compounding ratio R may be defined by one value. The target for the compounding ratio R may be defined by a range between two different values. The treatment liquid condition information is stored in advance in the storage medium of the controller 10.

### 6. Operation Example of First Supply Source 19a and Treating Unit 11

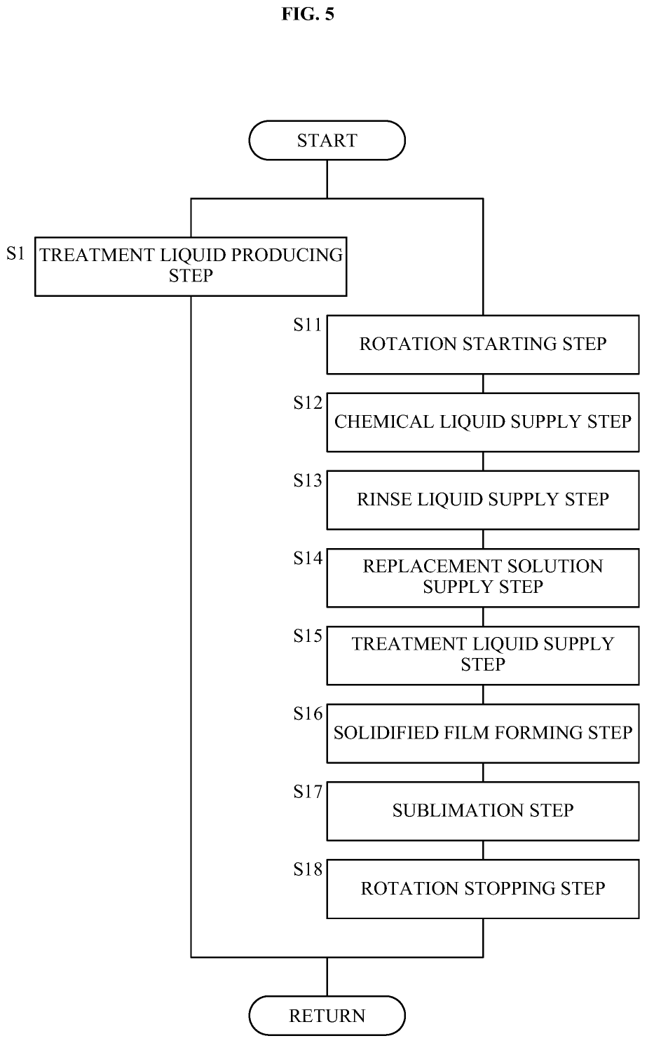

FIG. 5 is a flow chart showing procedures of the substrate treating method according to the embodiment. The substrate treating method includes a Step S1 and Steps S11 to S18. The Step S1 is executed by the first supply source 19a. The Steps S11 to S18 are substantially executed by the treating units 11. The Step S1 is executed in parallel with the Steps S11 to S18. The first supply source 19a and the treating units 11 operate in accordance with control by the controller 10.

The following describes the Steps S1 and S11 to S18 with reference to FIG. 4 as appropriate.

### Step S1: Treatment Liquid Producing Step

In the treatment liquid producing step, the treatment liquid g is produced.

The controller 10 controls the production unit 21 based on the treatment liquid condition information. The production unit 21 produces the treatment liquid g. The production unit 21 produces the treatment liquid g that satisfies the conditions of the treatment liquid g defined in the treatment liquid condition information. Specifically, the controller 10 controls the supply units 23a. 23b based on the target for the compounding ratio R. The supply unit 23a supplies the sublimable substance to the tank 22. The supply unit 23b supplies the solvent to the tank 22. The treatment liquid g is produced in the tank 22. The treatment liquid g has a compounding ratio R that conforms the target for the compounding ratio R. The treatment liquid g has an initial concentration V0 substantially determined by the compounding ratio R. The treatment liquid g is stored in the tank 22.

### Step S11: Rotation Starting Step

The substrate holder 13 holds the substrate W. The substrate W is held in a substantially horizontal posture. The rotation driving unit 14 rotates the substrate holder 13. As a result, the substrate W held by the substrate holder 13 starts to rotate.

In the Steps S12 to S17 described later, the substrate W continues to rotate, for example.

### Step S12: Chemical Liquid Supply Step

In the chemical liquid supply step, the chemical liquid is supplied to the substrate W.

The second supply unit 15b supplies the chemical liquid to the substrate W held by the substrate holder 13. Specifically, the valve 18b opens. The nozzle 16b dispenses the chemical liquid. The chemical liquid is supplied onto the upper surface of the substrate W. For example, the chemical liquid etches the substrate W. For example, the chemical liquid removes a natural oxide film from the substrate W.

Thereafter, the second supply unit 15b stops the supply of the chemical liquid to the substrate W. Specifically, the valve 18b closes. The nozzle 16b stops dispensing the chemical liquid.

### Step S13: Rinse Liquid Supply Step

In the rinse liquid supply step, the rinse liquid is supplied to the substrate W.

The third supply unit 15c supplies the rinse liquid to the substrate W held by the substrate holder 13. Specifically, the valve 18c opens. The nozzle 16c dispenses the rinse liquid. The rinse liquid is supplied onto the upper surface of the substrate W. For example, the rinse liquid cleans the substrate W. For example, the rinse liquid removes the chemical liquid from the substrate W.

Thereafter, the third supply unit 15c stops the supply of the rinse liquid to the substrate W. Specifically, the valve 18c closes. The nozzle 16c stops dispensing the rinse liquid.

### Step S14: Replacement Solution Supply Step

In the replacement solution supply step, the replacement solution is supplied to the substrate W.

The fourth supply unit 15d supplies the replacement solution to the substrate W held by the substrate holder 13. Specifically, the valve 18d opens. The nozzle 16d dispenses the replacement solution. The replacement solution is supplied onto the upper surface of the substrate W. The replacement solution removes the rinse liquid from the substrate W. The replacement solution replaces the rinse liquid on the substrate W.

Thereafter, the fourth supply unit 15d stops the supply of the replacement solution to the substrate W. Specifically, the valve 18d closes. The nozzle 16d stops dispensing the replacement solution.

### Step S15: Treatment Liquid Supply Step

In the treatment liquid supply step, the treatment liquid g is supplied to the substrate W.

The pressure feeding unit 31 supplies the treatment liquid g to the first supply unit 15a. The first supply unit 15a supplies the treatment liquid g to the substrate W held by the substrate holder 13. Specifically, the pump 34 feeds the treatment liquid g from the tank 22 to the first supply unit 15a. The pump 34 pressure-feeds the treatment liquid g from the tank 22 to the first supply unit 15a. The valve 18a opens. The nozzle 16a dispenses the treatment liquid g. The treatment liquid g is supplied onto the upper surface of the substrate W. The treatment liquid g removes the replacement solution from the substrate W. The treatment liquid g replaces the replacement solution on the substrate W.

Thereafter, the pressure feeding unit 31 stops the supply of the treatment liquid g to the first supply unit 15a. The first supply unit 15a stops the supply of the treatment liquid g to the substrate W. Specifically, the pump 34 stops. The valve 18a closes. The nozzle 16a stops dispensing the treatment liquid g.

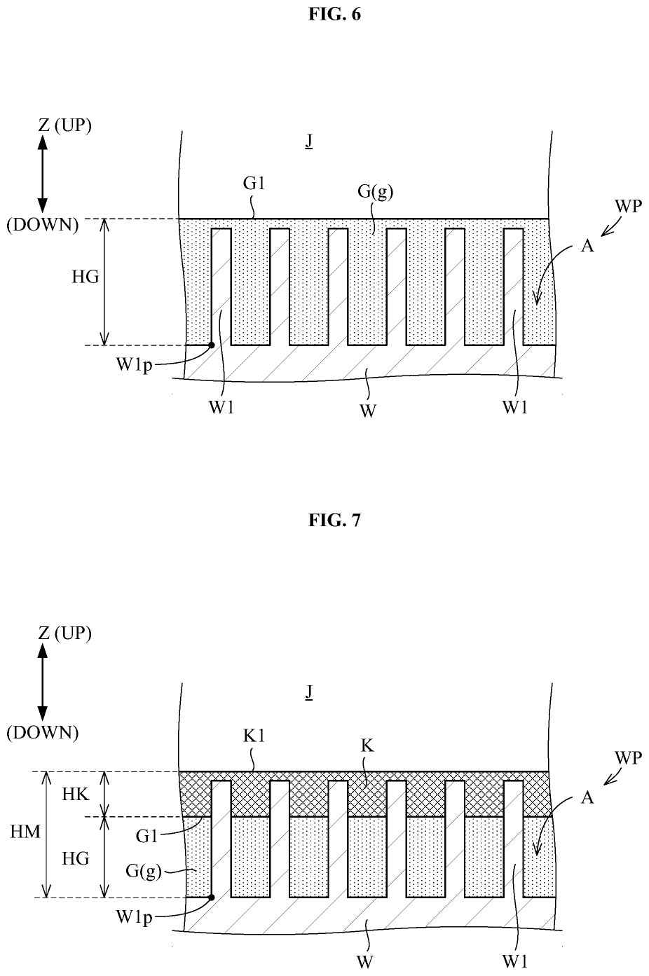

FIG. 6 is a view schematically showing the substrate W in the treatment liquid supply step. When the substrate W is held by the substrate holder 13, the pattern WP is positioned on the upper surface of the substrate W. When the substrate W is held by the substrate holder 13, the pattern WP is directed upward.

The treatment liquid g on the substrate W forms a liquid film G. The liquid film G is positioned on the substrate W. The liquid film G contacts the substrate W. The liquid film G covers the substrate W. The liquid film G covers the upper surface of the substrate W.

The pattern WP is entirely immersed in the liquid film G. The projections W1 are entirely immersed in the liquid film G. The recesses A are filled with the liquid film G. The recesses A are entirely filled only with the liquid film G.

The liquid film G has a top face G1. The top face G1 is positioned higher in level than the entire of the pattern WP. The top face G1 does not intersect with the pattern WP. The top face G1 is positioned higher in level than the entire of the projections W1. The top face G1 does not intersect with the projections W1.

Here, the replacement solution has already been removed from the substrate W by the treatment liquid g. Accordingly, there is no replacement solution on the substrate W. No replacement solution remains in the recesses A.

Gas J exists above the liquid film G. The pattern WP does not contact the gas J. The pattern WP is not exposed to the gas J. The projections W1 do not contact the gas J. The projections W1 are not exposed to the gas J.

The gas J contacts the liquid film G. The gas J contacts the top face G1. The top face G1 corresponds to a gas-liquid interface between the liquid film G and the gas J. Therefore, the pattern WP does not intersect with the gas-liquid interface between the liquid film G and the gas J. The projections W1 do not intersect with the gas-liquid interface between the liquid film G and the gas J.

In the treatment liquid supply step, a height position of the top face G1 may be adjusted additionally. For example, the height position of the top face G1 may be adjusted while the nozzle 16a supplies the treatment liquid g to the substrate W. For example, the height position of the top face G1 may be adjusted after the nozzle 16a stops supplying the treatment liquid g. For example, the height position of the top face G1 may be adjusted by adjusting a rotation speed of the substrate W. For example, the height position of the top face G1 may be adjusted by adjusting a period of rotation of the substrate W.

Here, adjusting the height position of the top face G1 corresponds to adjusting thickness HG of the liquid film G. The thickness HG of the liquid film G is, for example, a distance in the vertical direction Z between the base end W1p of the projection W1 and the top face G1.

### Step S16: Solidified Film Forming Step

In the solidified film forming step, the solvent evaporates from the treatment liquid g on the substrate W. In the solidified film forming step, a solidified film is formed on the substrate W. The solidified film contains the sublimable substance.

FIG. 7 is a view schematically showing the substrate W in the solidified film forming step. As described above, the solvent has a relatively high vapor pressure. At normal temperatures, the solvent has a higher vapor pressure than the sublimable substance. Accordingly, the solvent smoothly evaporates from the treatment liquid g on the substrate W. The solvent smoothly changes from a liquid to gas.

When the solvent evaporates from the treatment liquid g on the substrate W, the solvent is removed from the treatment liquid g on the substrate W. As the solvent evaporates from the treatment liquid g on the substrate W, the amount of the solvent contained in the liquid film G decreases. As the amount of the solvent contained in the liquid film G decreases, the concentration V of the sublimable substance in the liquid film G increases. The concentration V of the sublimable substance in the liquid film G increases from the initial concentration V0.

Eventually, the sublimable substance in the liquid film G starts to precipitate on the substrate W. That is, the sublimable substance changes from the solute of the treatment liquid g to the solid phase sublimable substance. The solid phase sublimable substance forms a solidified film K. The solidified film K does not contain a solvent. The solidified film K is a solid. The solidified film K is formed on the substrate W.

The liquid film G gradually decreases due to evaporation of the solvent and precipitation of the sublimable substance. The liquid film G gradually changes to the solidified film K due to the precipitation of the sublimable substance. The solidified film K gradually increases due to the precipitation of the sublimable substance. The solidified film K gradually grows.

First, the upper portion of the liquid film G is changed to the solidified film K. The solidified film K is located above the liquid film G. The solidified film K covers the top face G1 of the liquid film G.

When the solidified film K entirely covers the top face G1, the solidified film K separates the liquid film G from the gas J. The liquid film G contacts the solidified film K. The top face G1 of the liquid film G contacts the solidified film K. The liquid film G does not contact the gas J. The top face G1 does not contact the gas J. The gas-liquid interface between the liquid film G and the gas J disappears. The gas J contacts the solidified film K. The gas J contacts a top face K1 of the solidified film K.

Therefore, the pattern WP does not intersect with the gas-liquid interface. The liquid film G does not apply a significant force on the pattern WP. The projections W1 do not intersect with the gas-liquid interface. The liquid film G does not apply a significant force to the projections W1.

The solidified film K has thickness HK. The thickness HK of the solidified film K is, for example, a distance in the vertical direction Z between the top face G1 of the liquid film G and the top face K1 of the solidified film K.

As the solidified film K increases, the liquid film G decreases. As the thickness HK of the solidified film K increases, the thickness HG of the liquid film G decreases. As the thickness HK of the solidified film K increases, the height position of the top face G1 is lowered. The liquid film G gradually decreases without applying any significant force to the projections W1. The solvent is removed from the substrate W without applying any significant force to the projections W1.

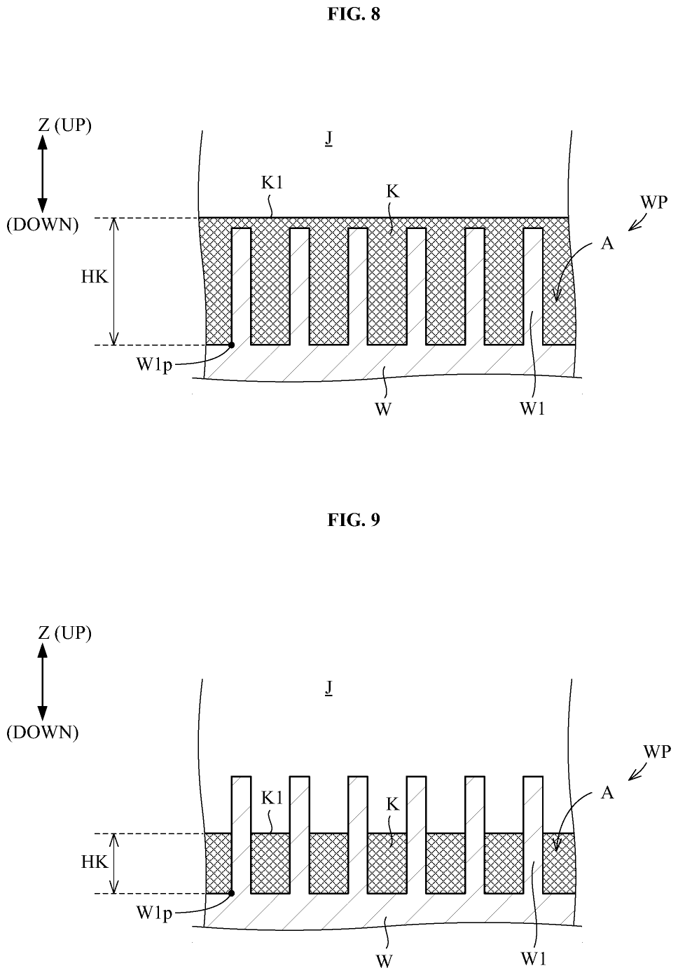

FIG. 8 is a view schematically showing the substrate W in the solidified film forming step. FIG. 8 schematically shows the substrate W when the solidified film forming step completes, for example. Only the solidified film K exists on the substrate W. The liquid film G entirely disappears from the substrate W when the solidified film forming step completes. No liquid film G remains in the recesses A. The solvent entirely disappears from the substrate W. No solvent also remains in the recesses A.

The solidified film K extends to the base end W1p of the substrate W. The recesses A are filled with the solidified film K. The recesses A are entirely filled only with the solidified film K. After the liquid film G entirely disappears from the substrate W, the thickness HK of the solidified film K is, for example, a distance in the vertical direction Z between the base end W1p of the projection W1 and the top face K1 of the solidified film K.

The pattern WP contacts the solidified film K. The solidified film K supports the pattern WP. The solidified film K protects the pattern WP. For example, the solidified film K prevents the pattern WP from collapsing. The projections W1 contact the solidified film K. The solidified film K supports the projections W1. The solidified film K protects the projections W1. For example, the solidified film K prevents the projections W1 from collapsing.

### Step S17: Sublimation Step

In the sublimation step, the solidified film K sublimates.

The fifth supply unit 15e supplies a dry gas to the substrate W held by the substrate holder 13. Specifically, the valve 18e opens. The nozzle 16e dispenses the dry gas. The nozzle 16e blows out the dry gas to the substrate W. The dry gas is supplied onto the upper surface of the substrate W. The dry gas is supplied to the solidified film K. The solidified film K is exposed to the dry gas. As a result, the solidified film K sublimates. The solidified film K changes to gas without being a liquid. Such sublimation of the solidified film K causes the solidified film K to be removed from the substrate W.

Thereafter, the fifth supply unit 15e stops the supply of the dry gas to the solidified film K. Specifically, the valve 18e closes. The nozzle 16e stops blowing out of the dry gas.

FIG. 9 is a view schematically showing the substrate W in the sublimation step. As the solidified film K sublimates, the solidified film K gradually decreases. As the solidified film K sublimates, the height position of the top face K1 of the solidified film K is lowered. As the solidified film K sublimates, the thickness HK of the solidified film K gradually decreases. As the solidified film K sublimates, the solidified film K gradually becomes thinner.

The sublimable substance has sublimability. Therefore, the sublimation of the solidified film K may start before the liquid film G disappears from the substrate W. A part of the period during which the sublimation step is executed may overlap with a part of the period during which the solidified film forming step is executed.

The pattern WP starts to be exposed to the gas J. The projections W1 start to be exposed to the gas J.

When the solidified film K sublimates, the solidified film K does not change to a liquid. Accordingly, in the sublimation step, there is no liquid on the substrate W. In the sublimation step, there is no liquid in the recesses A. In the sublimation step, the gas-liquid interface is not generated in the vicinity of the pattern WP.

Therefore, the pattern WP does not intersect with the gas-liquid interface. The solidified film K does not apply any significant force on the pattern WP. The solidified film K is removed from the substrate W without applying any significant force to the pattern WP. The projections W1 do not intersect with the gas-liquid interface. The solidified film K does not apply any significant force to the projections W1. The solidified film K is removed from the substrate W without applying any significant force to the projections W1.

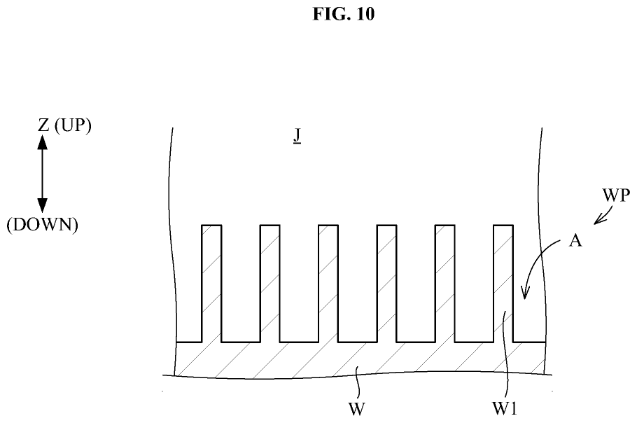

FIG. 10 is a view schematically showing the substrate W in the sublimation step. FIG. 10 schematically shows, for example, the substrate W when the sublimation step completes. The solidified film K entirely disappears from the substrate W when the sublimation step completes. There is no liquid on the substrate W. The pattern WP is entirely exposed to the gas J. The projections W1 are entirely exposed to the gas J. The recesses A are entirely filled with only the gas J. The substrate W is dried.

The treatment in the treatment liquid supply step, the solidified film forming step, and the sublimation step described above are examples of the dry treatment. The treatment in the treatment liquid supply step, the solidified film forming step, and the sublimation step described above correspond to examples of use of the treatment liquid g. The treatment liquid g is used under an environment of normal temperatures. The treatment liquid g is used under an environment of normal pressure.

### Step S18: Rotation Stopping Step

The rotation driving unit 14 stops rotating the substrate holder 13. The substrate W held by the substrate holder 13 stops rotation. The substrate W rests. The treating units 11 complete treatment on the substrate W.

### 7. Technical Meanings of Treatment Liquid g

The technical meanings of the treatment liquid g will be described with reference to Examples 1a to 1h and 2a to 2h and Comparative Examples 1a to 1h and 2a to 2h. Hereinafter. Examples 1a to 1h are collectively referred to as Example Group 1. Examples 2a to 2h are collectively referred to as Example Group 2. Comparative Examples 1a to 1h are collectively referred to as Comparative Example Group 1. Comparative Examples 2a to 2h are collectively referred to as Comparative Example Group 2.

The following describes conditions in Example Group 1. The only difference between Examples 1a to 1h is the compounding ratio R. Conditions other than the compounding ratio R are common among Examples 1a to 1h.

Specifically, in Examples 1a to 1h, the substrate W is treated in the treatment liquid supply step, the solidified film forming step, and the sublimation step. More specifically, in Examples 1a to 1h, the substrate W is treated in the chemical liquid supply step, the rinse liquid supply step, the replacement solution supply step, the treatment liquid supply step, the solidified film forming step, and the sublimation step.

The chemical liquid used in the chemical liquid supply step is hydrofluoric acid. Hydrofluoric acid is a mixed liquid of hydrogen fluoride and water. The volume ratio of hydrogen fluoride to water is as follows.

Hydrogen fluoride:Water=1:10 (volume ratio)

The rinse liquid used in the rinse liquid supply step is deionized water (DIW). The replacement solution used in the replacement solution supply step is isopropyl alcohol.

The treatment liquid g used in the treatment liquid supply step consists of the sublimable substance and the solvent. The sublimable substance is 4-tert-butylphenol. The solvent is isopropyl alcohol (IPA).

The compounding ratio R of Example 1a is 2.5 Vol %. When the compounding ratio R is 2.5 vol %, the following equation holds.

Volume Q1g:Volume Q2g=1:40

The compounding ratios R of Examples 1b, 1c, 1d, 1e, 1f, 1g, and 1h are 5.0, 6.7, 10.0, 12.5, 16.7, 20.0, and 25.0 Vol %, respectively.

In the solidified film forming step, the substrate W is rotated at a rotation speed of 1.500 rpm.

In the sublimation step, the dry gas is supplied to the substrate W while the substrate W is rotated at a rotation speed of 1.500 rpm.

The following describes conditions of Example Group 2 and Comparative Example Groups 1 and 2. In Example Group 2, the sublimable substance is acetophenone oxime. In Comparative Example Group 1, the sublimable substance is cyclohexanone oxime. In Comparative Example Group 2, the sublimable substance is pinacolone oxime.

Conditions other than the sublimable substance are common between Examples 1a, 2a and Comparative Examples 1a, 2b. Conditions other than the sublimable substance are common between Examples 1b, 2b and Comparative Examples 1b, 2b. Conditions other than the sublimable substance are common between Examples 1c, 2c and Comparative Examples 1c, 2c. Conditions other than the sublimable substance are common between Examples 1d, 2d and Comparative Examples 1d, 2d. Conditions other than the sublimable substance are common between Examples 1e, 2e and Comparative Examples 1e, 2e. Conditions other than the sublimable substance are common between Examples 1f, 2f and Comparative Examples 1f, 2f. Conditions other than the sublimable substance are common between Examples 1g, 2g and Comparative Examples 1g, 2g. Conditions other than the sublimable substance are common between Examples 1h, 2h and Comparative Examples 1h, 2h.

The substrates W treated in Examples 1a to 1h and 2a to 2h and Comparative Examples 1a to 1h and 2a to 2h were evaluated by collapse rate D (%). The collapse rate D is a probability that the pattern WP on the substrate W collapses when the substrate W is treated. In other words, the collapse rate D is a probability that the projections W1 on the substrate W collapse when the substrate W is treated. The small collapse rate D means that the pattern WP is protected.

The collapse rate D is exemplified. The collapse rate D is, for example, a median dm (%) in a plurality of local collapse rates di. The median dm is one local collapse rate di located at the center in a sequence in which all the local collapse rates di are arranged in order of size. Each local collapse rate di (%) is a collapse rate in each local area Ei. i is any natural number from 1 to NE. NE is the number of local areas Ei. The number NE is a natural number of 2 or more. Each local area Ei is a minute region of the substrate W. Each local area Ei is magnified 50.000 times, for example, by a scanning electron microscope. An observer observes the pattern WP (projections W1) in each local area Ei. The observer evaluates the projections W1 in each local area Ei one by one. The observer determines the projections W1 in each local area Ei one by one. Specifically, the observer determines, for each projection W1, whether or not the projection W1 has collapsed. Here, the number of projections W1 evaluated in each local area Ei is defined as NPi. The number of the projections W1 determined in each local area Ei is defined as NPi. The number of the projections W1 determined to have collapsed in each local area Ei is defined as NTi. The number NTi is equal to or less than the number NPi. The local collapse rate di is a ratio of the number NTi to the number NPi. The local collapse rate di is defined by, for example, the following formula.

$$di = NTi / NPi * 100 ( \% )$$

Furthermore, in Examples 1a to 1h and 2a to 2h and Comparative Examples 1a to 1h and 2a to 2h, maximum height HM of the solidified film K was measured. The maximum height HM of the solidified film K is, for example, a distance in the vertical direction Z between the base end W1p of the projection W1 and the top face K1 of the solidified film K when the liquid film G starts to change to the solidified film K. The maximum height HM of the solidified film K is substantially equal to the thickness HG of the liquid film G immediately before the liquid film G changes to the solidified film K. For reference. FIG. 7 shows the maximum height HM. The maximum height HM of the solidified film K can also be said to be the initial height of the solidified film K. More specifically, the maximum height HM of the solidified film K can also be said to be the height of the solidified film K at the initial stage when the solidified film K starts to be produced. The maximum height HM is, for example, the maximum value of the distance in the vertical direction Z between the base end W1p of the projection W1 and the top face K1 of the solidified film K.

The maximum height HM of the solidified film K was measured using a film thickness meter. The film thickness meter is, for example, an optical interference film thickness meter. The optical interference film thickness meter detects interference light reflected from the liquid film G or the solidified film K, and acquires a measured value of the thickness HG of the liquid film G or the film thickness HK of the solidified film K based on the detected interference light. The interference light includes light reflected by the surface of the liquid film G or the solidified film K and light reflected by the back surface of the liquid film G or the solidified film K.

Here, the liquid film G has relatively high transparency. The liquid film G appropriately reflects light. Therefore, the thickness HG of the liquid film G is appropriately measured by a film thickness meter. On the other hand, the solidified film K has transparency lower than the transparency of the liquid film G. The solidified film K does not appropriately reflect light. Therefore, the film thickness HK of the solidified film K is not appropriately measured by the film thickness meter. Accordingly, when the liquid film G changes to the solidified film K, the measured value of the film thickness meter changes greatly.

Therefore, the maximum height HM of the solidified film K was estimated by the following method. The film thickness meter continues to measure the liquid film G and the solidified film K on the substrate W from the treatment liquid supply step to the solidified film forming step. From the measurement result of the film thickness meter, one measured value immediately before the measured value greatly changes with time is specified as transition measured value. The transition measured value is regarded as the thickness HG of the liquid film G immediately before the liquid film G changes to the solidified film K. Furthermore, the transition measured value is regarded as the maximum height HM of the solidified film K.

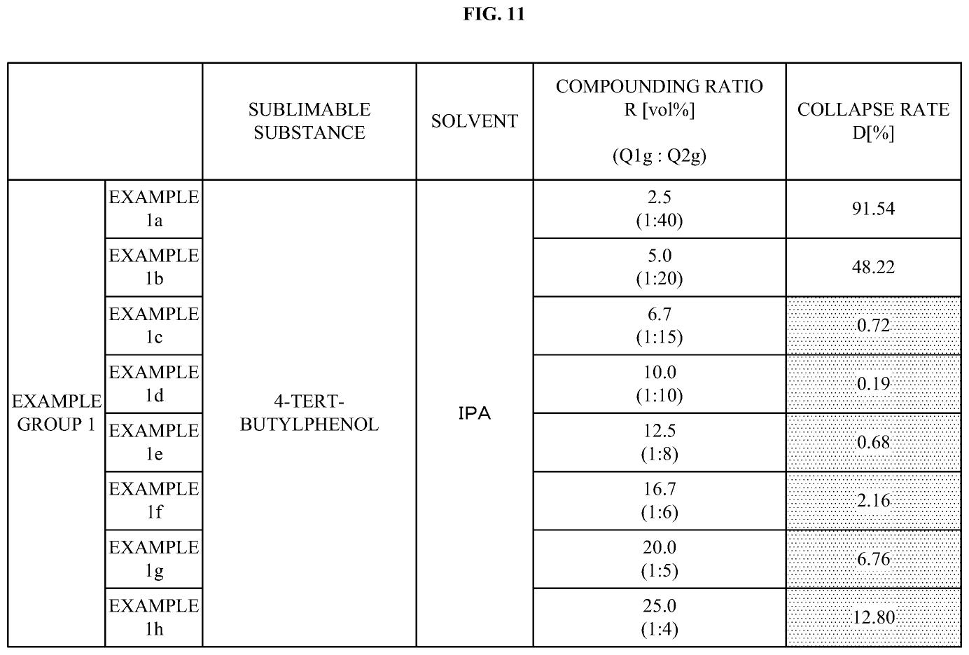

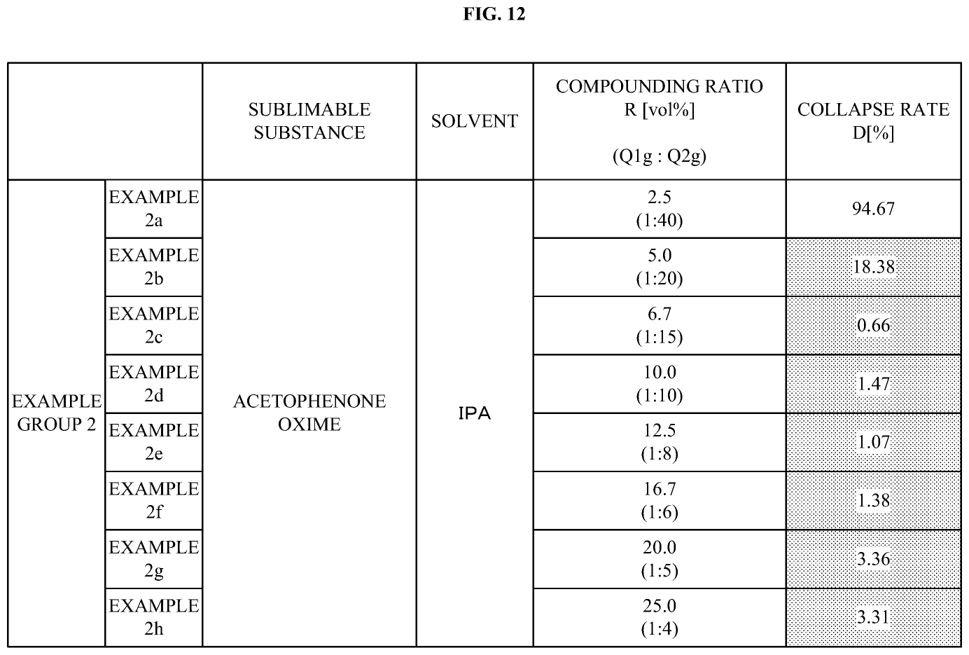

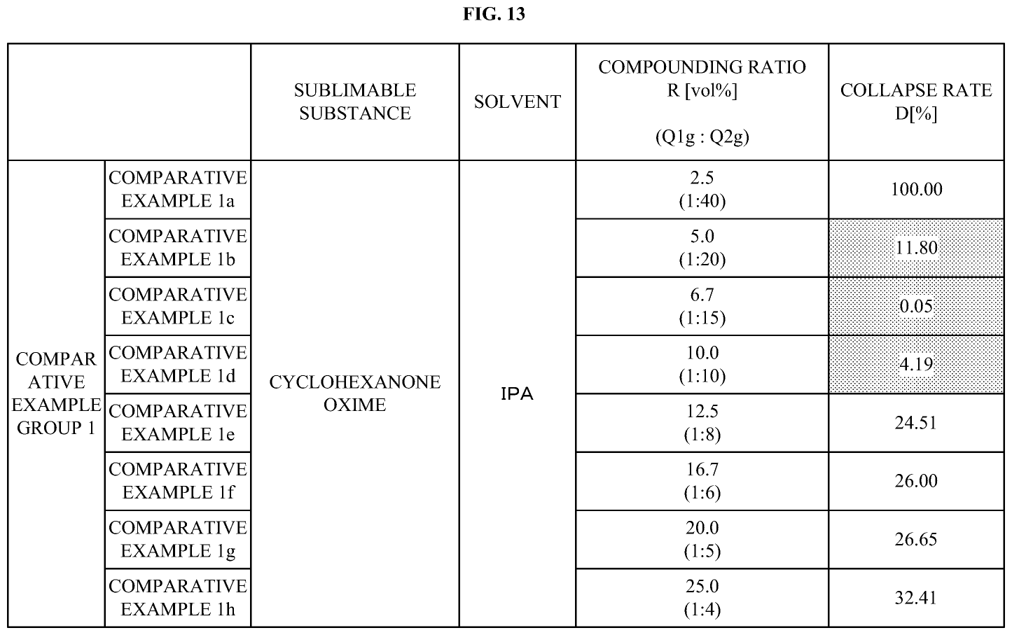

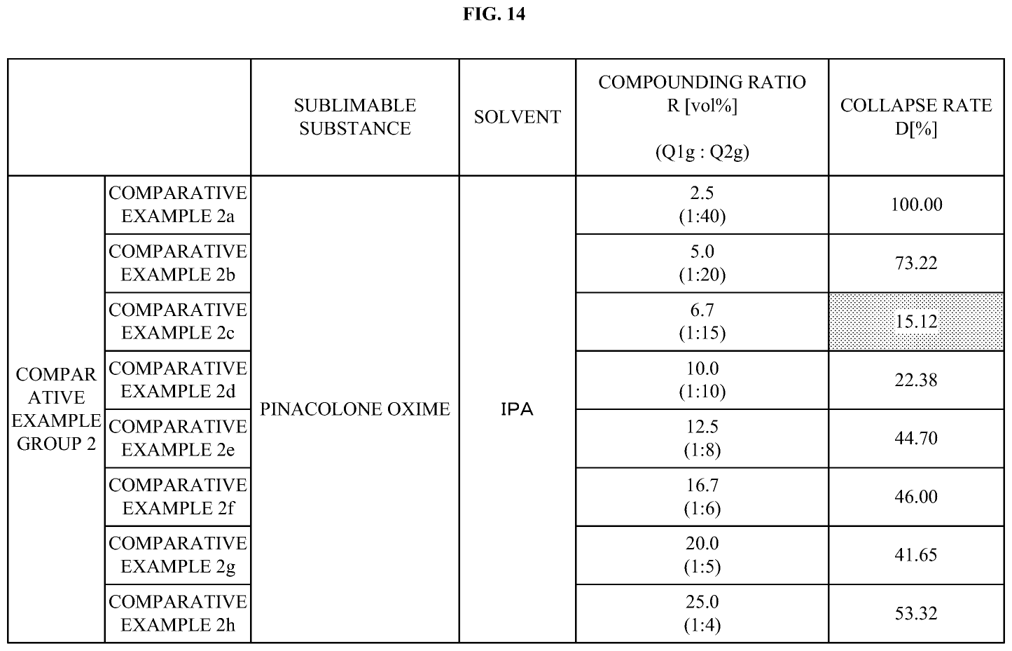

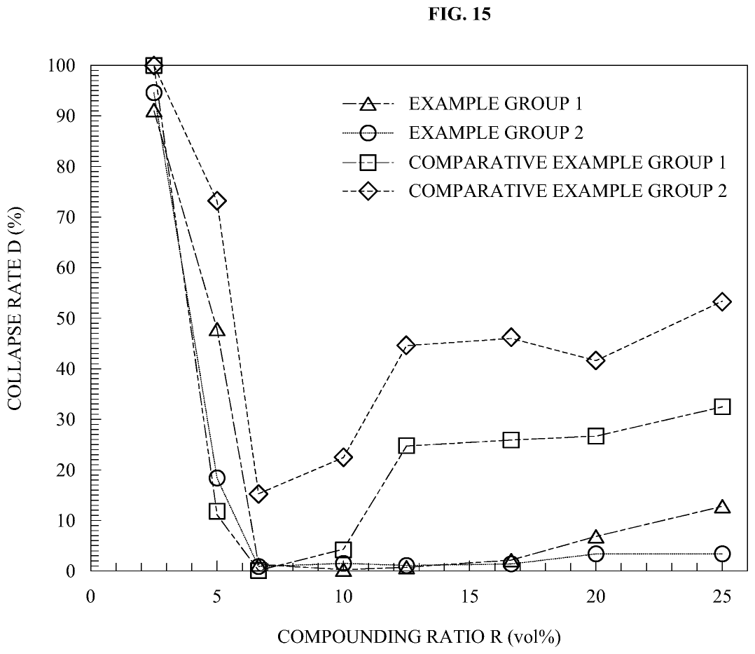

FIG. 11 is a table showing the collapse rates D of the substrates W treated in Example Group 1. FIG. 12 is a table showing the collapse rates D of the substrates W treated in Example Group 2. FIG. 13 is a table showing the collapse rates D of the substrates W treated in Comparative Example Group 1. FIG. 14 is a table showing the collapse rates D of the substrates W treated in Comparative Example Group 2. In FIGS. 11 to 14, the collapse rates D of 20% or less are clearly indicated by gray tone. FIG. 15 is a graph showing relationships between the compounding ratios R and the collapse rates D in Example Groups 1 and 2 and Comparative Example Groups 1 and 2. In the graph of FIG. 15, the horizontal axis represents the compounding ratio R. and the vertical axis represents the collapse rate D.

Reference is made to FIG. 11. In Example Group 1, when the compounding ratio R changes, the collapse rate D changes. By changing the compounding ratio R, a plurality of collapse rates D are obtained. In other words, at different compounding ratios R, a plurality of collapse rates D are obtained. Among the plurality of collapse rates D, the smallest collapse rate D is referred to as minimum collapse rate Da. The minimum collapse rate Da of Example Group 1 is 5.00% or less. The minimum collapse rate Da of Example Group 1 is 1.00% or less. Specifically, the minimum collapse rate Da of Example Group 1 is 0.19%.

The compounding ratio R when the collapse rate D is the minimum collapse rate Da is referred to as optimum compounding ratio Ra. The optimum compounding ratio Ra of Example Group 1 is 10 vol %.

Reference is made to FIG. 12. In Example Group 2, a plurality of collapse rates D are obtained by changing the compounding ratio R. The minimum collapse rate Da of Example Group 2 is 5.00% or less. The minimum collapse rate Da of Example Group 2 is 1.00% or less. Specifically, the minimum collapse rate Da of Example Group 2 is 0.66%. The optimum compounding ratio Ra of Example Group 2 is 6.7 vol %.

Reference is made to FIG. 13. In Comparative Example Group 1, a plurality of collapse rates D are obtained by changing the compounding ratio R. The minimum collapse rate Da of Comparative Example Group 1 is 0.05%. The optimum compounding ratio Ra of Comparative Example Group 1 is 6.7 vol %.

Reference is made to FIG. 14. In Comparative Example Group 2, a plurality of collapse rates D are obtained by changing the compounding ratio R. The minimum collapse rate Da of Comparative Example Group 2 is 15.12%. The optimum compounding ratio Ra of Comparative Example Group 2 is 6.7 vol %.

Reference is made to FIGS. 11 to 14. In Example Group 1, the collapse rate D decreases as the compounding ratio R increases from 2.5 vol % to the optimum compounding ratio Ra. In Example Group 1, the collapse rate D increases as the compounding ratio R increases from the optimum compounding ratio Ra to 25 vol %. Example Group 2 and Comparative Example Groups 1 and 2 also have the same tendency as Example Group 1.

In FIG. 15, the curves (polygonal lines) of Example Group 1 curve convexly downward. Similarly, each of the curves of Example Group 2 and Comparative Example Groups 1 and 2 curves convexly downward.

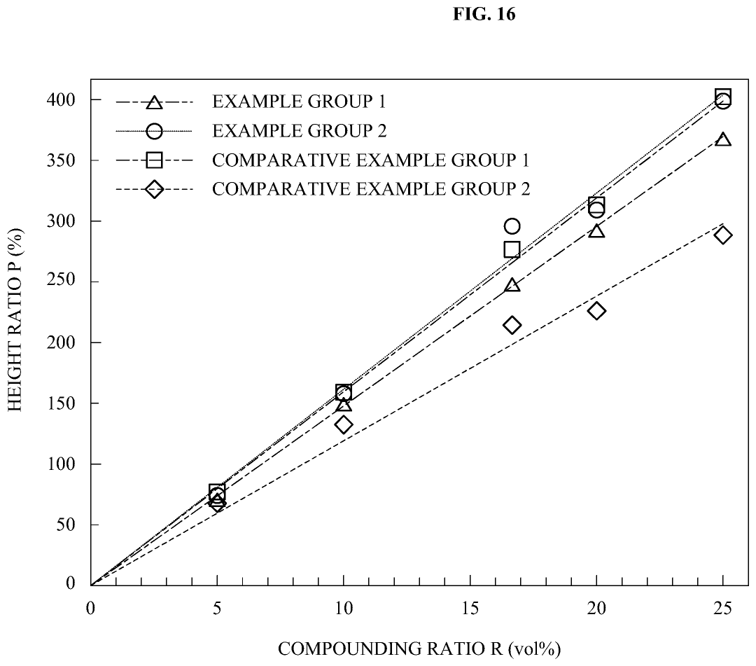

FIG. 16 is a graph showing relationships between the compounding ratios R and the maximum heights HM of the solidified films K in Example Groups 1 and 2 and Comparative Example Groups 1 and 2. In the graph of FIG. 16, the horizontal axis represents the compounding ratio R. The vertical axis represents height ratio P (%). Here, the height ratio P is a ratio of the maximum height HM of the solidified film K to the height HP of the pattern WP. Specifically, the height ratio P is defined by the following formula.

$$Height ratio P = HM / HP * 100 ( \% )$$

In Example Group 1, the height ratio P depends on the compounding ratio R. In Example Group 1, the height ratio P increases in proportion to the compounding ratio R. In Example Group 1, when the compounding ratio is 5 vol %, the height ratio P is less than 100%. In Example Group 1, when the compounding ratio is 10 vol % or more, the height ratio P is more than 100%. Example Group 2 and Comparative Example Groups 1 and 2 also have the same tendency as Example Group 1.

In Example Group 1, when the compounding ratio R is 16.7 vol %, the height ratio P is about 250%. In Example Group 1, when the compounding ratio R is 20.0 vol %, the height ratio P is about 300%. In Example Group 1, when the compounding ratio R is 25.0 vol %, the height ratio P is about 350%. In other words, in Example Group 1, when the compounding ratio R is 16.7 vol %, the maximum height HM of the solidified film K is about 2.5 times the height HP of the pattern WP. In Example Group 1, when the compounding ratio R is 20.0 vol %, the maximum height HM of the solidified film K is about 3.0 times the height HP of the pattern WP. In Example Group 1, when the compounding ratio R is 25.0 vol %, the maximum height HM of the solidified film K is about 3.5 times the height HP of the pattern WP.

In Example Group 2, when the compounding ratio R is 20.0 vol %, the height ratio P is about 300%. In Example Group 2, when the compounding ratio R is 25.0 vol %, the height ratio P is about 400%. In other words, in Example Group 2, when the compounding ratio R is 20.0 vol %, the maximum height HM of the solidified film K is about 3.0 times the height HP of the pattern WP. In Example Group 2, when the compounding ratio R is 25.0 vol %, the maximum height HM of the solidified film K is about 4.0 times the height HP of the pattern WP.

The value of the height HP is constant regardless of the compounding ratio R. Therefore, in Example Group 1, the maximum height HM of the solidified film K depends on the compounding ratio R. In Example Group 1, the maximum height HM of the solidified film K increases in proportion to the compounding ratio R. Example Group 2 and Comparative Example Groups 1 and 2 also have the same tendency as Example Group 1.

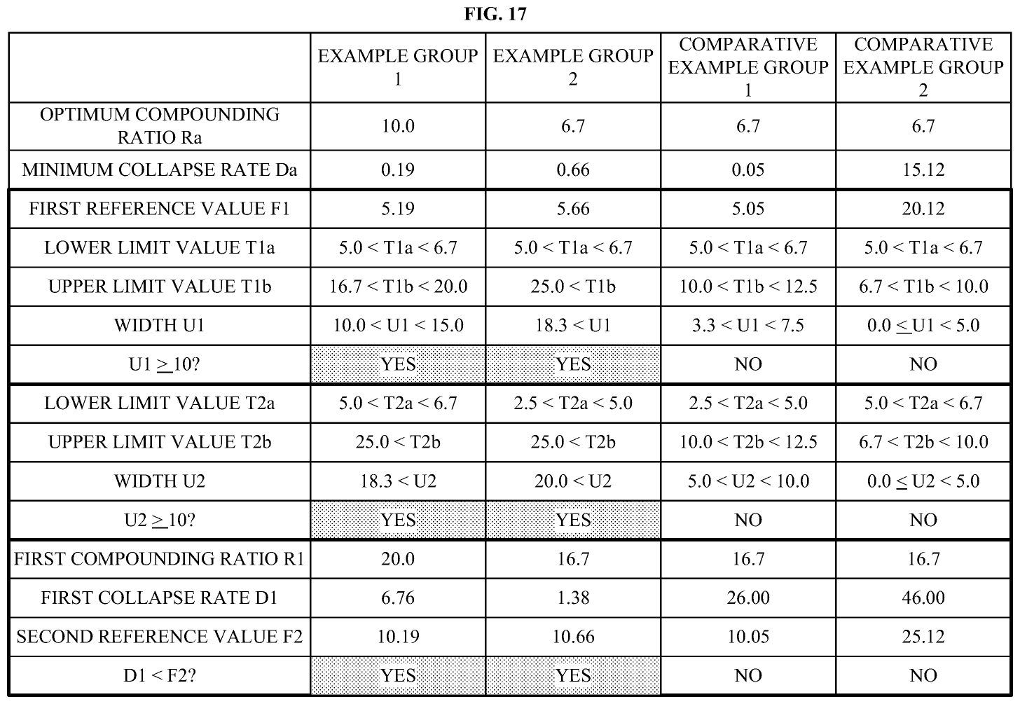

FIG. 17 is a table obtained by analyzing the collapse rates D of the substrates W treated in Example Groups 1 and 2 and Comparative Example Groups 1 and 2. The optimum compounding ratios Ra of Example Groups 1 and 2 and Comparative Example Groups 1 and 2 are as described above. The minimum collapse rates Da of Example Groups 1 and 2 and Comparative Example Groups 1 and 2 are also as described above.

FIG. 17 shows first reference value F1 (%). The first reference value F1 is a value obtained by adding 5% to the minimum collapse rate Da. The first reference value F1 of Example Group 1 is 5.19%. The first reference value F1 of Example Group 2 is 5.66%. The first reference value F1 of Comparative Example Group 1 is 5.05%. The first reference value F1 of Comparative Example Group 2 is 20.12%.

FIG. 17 shows lower limit value T1a (vol %) and upper limit value T1b (vol %). The lower limit value T1a is the minimum value of the compounding ratio R when the collapse rate D is equal to or less than the first reference value F1. The upper limit value T1b is the maximum value of the compounding ratio R when the collapse rate D is equal to or less than the first reference value F1. The lower limit value T1a and the upper limit value T1b define first range T1. That is, the first range T1 is a range from the lower limit value T1a to the upper limit value T1b. The first range T1 is a range of the compounding ratio R when the collapse rate D is equal to or less than the first reference value F1.

FIG. 17 shows width U1. The width U1 is a width of the first range T1. The width U1 is a difference between the lower limit value T1a and the upper limit value T1b.

The following describes the first range T1 of Example Group 1 with reference to FIGS. 11 and 17. When the compounding ratio R is 5.0 vol %, the collapse rate D is higher than the first reference value F1. When the compounding ratio R is 6.7 vol %, the collapse rate D is lower than the first reference value F1. Therefore, the lower limit value T1a is larger than 5.0 vol % and smaller than 6.7 vol %. When the compounding ratio R is 16.7 vol %, the collapse rate D is lower than the first reference value F1. When the compounding ratio R is 20.0 vol %, the collapse rate D is higher than the first reference value F1. Therefore, the upper limit value T1b is larger than 16.7 vol % and smaller than 20.0 vol %. Therefore, the width U1 of Example Group 1 is larger than 10.0 and smaller than 15.0.

The following describes the first range T1 of Example Group 2 with reference to FIGS. 12 and 17. The lower limit value T1a is larger than 5.0 vol % and smaller than 6.7 vol %. The upper limit value T1b is larger than 25.0 vol %. Therefore, the width U1 of Example Group 2 is larger than 18.3.

The following describes the first range T1 of Comparative Example Group 1 with reference to FIGS. 13 and 17. The lower limit value T1a is larger than 5.0 vol % and smaller than 6.7 vol %. The upper limit value T1b is larger than 10.0 vol % and smaller than 12.5 vol %. Therefore, the width U1 of Comparative Example Group 1 is larger than 3.3 and smaller than 7.5.

The following describes the first range T1 of Comparative Example Group 2 with reference to FIGS. 14 and 17. The lower limit value T1a is larger than 5.0 vol % and smaller than 6.7 vol %. The upper limit value T1b is larger than 6.7 vol % and smaller than 10.0 vol %. Therefore, the width U1 of Comparative Example Group 2 is larger than 0 and smaller than 5.

In FIG. 17. “YES” or “NO” is indicated in the column of “Width U1>10?”. “YES” means that the width U1 is 10 or more. “NO” means that the width U1 is less than 10. The widths U1 of Example Groups 1 and 2 are each “YES”. The width U1 of Comparative Example Groups 1 and 2 are each “NO”. That is, the widths U1 of Example Groups 1 and 2 are each 10 vol % or more. The widths U1 of Comparative Example Groups 1 and 2 are each less than 10 vol %.

FIG. 17 shows lower limit value T2a (vol %) and upper limit value T2b (vol %). The lower limit value T2a is the minimum value of the compounding ratio R when the collapse rate D is 20% or less. The upper limit value T2b is the maximum value of the compounding ratio R when the collapse rate D is 20% or less. The lower limit value T2a and the upper limit value T2b define the second range T2. That is, the second range T2 is a range from the lower limit value T2a to the upper limit value T2b. The second range T2 is a range of the compounding ratio R when the collapse rate D is 20% or less.

FIG. 17 shows width U2. The width U2 is a width of the second range T2. The width U2 is a difference between the lower limit value T2a and the upper limit value T2b.

The following describes the second range T2 of Example Group 1 with reference to FIGS. 11 and 17. When the compounding ratio R is 5.0 vol %, the collapse rate D is higher than 20%. When the compounding ratio R is 6.7 vol %, the collapse rate D is lower than 20%. Therefore, the lower limit value T2a is larger than 5.0 vol % and smaller than 6.7 vol %. When the compounding ratio R is 25.0 vol %, the collapse rate D is lower than 20%. Thus, the upper limit value T2b is larger than 25.0 vol %. Therefore, the width U2 of Example Group 1 is larger than 18.3.

The following describes the second range T2 of Example Group 2 with reference to FIGS. 12 and 17. The lower limit value T2a is larger than 2.5 vol % and smaller than 5.0 vol %. The upper limit value T2b is larger than 25.0 vol %. Therefore, the width U2 of Example Group 2 is larger than 20.0.

The following describes the second range T2 of Comparative Example Group 1 with reference to FIGS. 13 and 17. The lower limit value T2a is larger than 2.5 vol % and smaller than 5.0 vol %. The upper limit value T2b is larger than 10.0 vol % and smaller than 12.5 vol %. Therefore, the width U2 of Comparative Example Group 1 is larger than 5.0 and smaller than 10.0.

The following describes the second range T2 of Comparative Example Group 2 with reference to FIGS. 14 and 17. The lower limit value T2a is larger than 5.0 vol % and smaller than 6.7 vol %. The upper limit value T2b is larger than 6.7 vol % and smaller than 10.0 vol %. Therefore, the width U2 of Comparative Example Group 2 is larger than 0 and smaller than 5.0.

In FIG. 17. “YES” or “NO” is indicated in the column of “Width U2>10?”. “YES” means that the width U2 is 10 or more. “NO” means that the width U2 is less than 10. The widths U2 of Example Groups 1 and 2 are each “YES”. The widths U2 of Comparative Example Groups 1 and 2 are each “NO”. That is, the widths U2 of Example Groups 1 and 2 are each 10 vol % or more. The widths U2 of Comparative Example Groups 1 and 2 are each less than 10 vol %.

FIG. 17 shows first compounding ratio R1 (vol %). The first compounding ratio R1 is a value obtained by adding 10 vol % to the optimum compounding ratio Ra. The first compounding ratio R1 of Example Group 1 is 20.0 vol %. The first compounding ratio R1 of Example Group 2 is 16.7 vol %. The first compounding ratio R1 of Comparative Example Group 1 is 16.7 vol %. The first compounding ratio R1 of Comparative Example Group 2 is 16.7 vol %.

FIG. 17 shows first collapse rate D1 (%). The first collapse rate D1 is the collapse rate D when the compounding ratio R is the first compounding ratio R1. The first collapse rate D1 of Example Group 1 is 6.76%. The first collapse rate D1 of Example Group 2 is 1.38%. The first collapse rate D1 of Comparative Example Group 1 is 26.00%. The first collapse rate D1 of Comparative Example Group 2 is 46.00%.

FIG. 17 shows second reference value F2 (%). The second reference value F2 is a value obtained by adding 10% to the minimum collapse rate Da. The second reference value F2 of Example Group 1 is 10.19%. The second reference value F2 of Example Group 2 is 10.66%. The second reference value F2 of Comparative Example Group 1 is 10.05%. The second reference value F2 of Comparative Example Group 2 is 25.12%.

In FIG. 17. “YES” or “NO” is indicated in the column of “D1<F2?”. “YES” means that the first collapse rate D1 is lower than the second reference value F2. “NO” means that the first collapse rate D1 is equal to or more than the second reference value F2. The relationship between the first collapse rate D1 and the second reference value F2 in Example Group 1 is “YES”. The relationship between the first collapse rate D1 and the second reference value F2 in Example Group 2 is “YES”. The relationship between the first collapse rate D1 and the second reference value F2 in Comparative Example Group 1 is “NO”. The relationship between the first collapse rate D1 and the second reference value F2 in Comparative Example Group 2 is “NO”. That is, in Example Groups 1 and 2, the first collapse rate D1 is lower than the second reference value F2. In Comparative Example Groups 1 and 2, the first collapse rate D1 is equal to or more than the second reference value F2.

In summary, in Example Groups 1 and 2, the first range T1 had a width U1 of 10 or more. In Example Groups 1 and 2, the width U1 of the first range T1 is 10 or more. In Example Groups 1 and 2, the second range T2 had a width U2 of 10 or more. In Example Groups 1 and 2, the width U2 of the second range T2 is 10 or more. In Example Groups 1 and 2, the first collapse rate D1 is lower than the second reference value F2. On the other hand, in Comparative Example Groups 1 and 2, the first range T1 does not have a width U1 of 10 or more. In Comparative Example Groups 1 and 2, the width U1 of the first range T1 is less than 10. In Comparative Example Groups 1 and 2, the second range T2 does not have a width U2 of 10 or more. In Comparative Example Groups 1 and 2, the width U2 of the second range T2 is less than 10. In Comparative Example Groups 1 and 2, the first collapse rate D1 is equal to or more than the second reference value F2. The first range T1 of Example Group 1 is wider than the first ranges T1 of Comparative Example Groups 1 and 2. The second range T2 of Example Group 1 is wider than the second ranges T2 of Comparative Example Groups 1 and 2. The first range T1 of Example Group 2 is wider than the first ranges T1 of Comparative Example Groups 1 and 2. The second range T2 of Example Group 2 is wider than the second ranges T2 of Comparative Example Groups 1 and 2. Here, the first range T1 corresponds to a range of the compounding ratio R for appropriately treating the substrate W. The second range T2 also corresponds to a range of the compounding ratio R for appropriately treating the substrate W. As described above, in Example Groups 1 and 2, the range of the compounding ratio R in which the substrate W can be appropriately treated is wider than that in Comparative Example Groups 1 and 2. Specifically, the range of the compounding ratio R in which the substrate W can be appropriately treated in Example Groups 1 and 2 is wider than the range of the compounding ratio R in which the substrate W can be appropriately treated in Comparative Example Groups 1 and 2. The range of the compounding ratio R in which the substrate W can be appropriately treated corresponds to a process window for the compounding ratio R. Therefore, in Example Groups 1 and 2, the process window for the compounding ratio R is wider than that in Comparative Example Groups 1 and 2. Specifically, the process window for the compounding ratio R in Example Groups 1 and 2 is wider than the process window for the compounding ratio R in Comparative Example Groups 1 and 2. Example Groups 1 and 2 are superior to Comparative Example Groups 1 and 2 in terms of the width of the process window.

Furthermore, in Example Group 1, the first range T1 includes a compounding ratio R of 16.7 vol % or more. When the compounding ratio R is 16.7 vol %, the height ratio P is about 250%. Therefore, in Example Group 1, even when the maximum height HM of the solidified film K is about 2.5 times the height HP of the pattern WP, the collapse rate D is equal to or less than the first reference value F1. Accordingly, in Example Group 1, even when the maximum height HM of the solidified film K is about 2.5 times the height HP of the pattern WP, the substrate W is appropriately treated.

In Example Group 1, the second range T2 includes a compounding ratio R of 25.0 vol % or more. When the compounding ratio R is 25.0 vol %, the height ratio P is about 350%. Therefore, in Example Group 1, even when the maximum height HM of the solidified film K is about 3.5 times the height HP of the pattern WP, the collapse rate D is 20% or less. Accordingly, in Example Group 1, even when the maximum height HM of the solidified film K is about 3.5 times the height HP of the pattern WP, the substrate W is appropriately treated.

In Example Group 2, the first range T1 includes a compounding ratio R of 25.0 vol % or more. When the compounding ratio R is 25.0 vol %, the height ratio P is about 400%. Therefore, in Example Group 2, even when the maximum height HM of the solidified film K is about 4.0 times the height HP of the pattern WP, the collapse rate D is equal to or less than the first reference value F1. Accordingly, in Example Group 2, even when the maximum height HM of the solidified film K is about 4.0 times the height HP of the pattern WP, the substrate W is appropriately treated.

In Example Group 2, the second range T2 includes a compounding ratio R of 25.0 vol % or more. When the compounding ratio R is 25.0 vol %, the height ratio P is about 400%. Therefore, in Example Group 2, even when the maximum height HM of the solidified film K is about 4.0 times the height HP of the pattern WP, the collapse rate D is 20% or less. Accordingly, in Example Group 2, even when the maximum height HM of the solidified film K is about 4.0 times the height HP of the pattern WP, the substrate W is appropriately treated.

### 8. Mechanism for Collapse of Pattern WP (1)

The Inventors have studied technical matters contributing to expansion of the process window for the compounding ratio R. As a result, the Inventors have inferred that the vapor pressure of the sublimable substance is important for expansion of the process window. In Example Groups 1 and 2, the sublimable substance has a vapor pressure at normal temperatures of 1.0 Pa or less. In Comparative Example Groups 1 and 2, the sublimable substance has a vapor pressure at normal temperatures of more than 1.0 Pa. The Inventors inferred that this difference significantly affected the width of the process window. Specifically, the Inventors assumed as follows for the mechanism for collapse of the pattern WP.

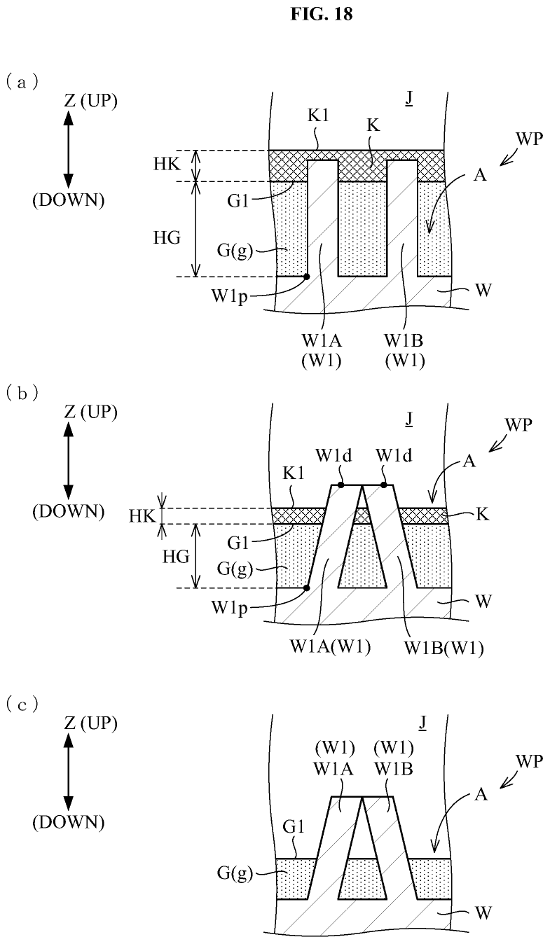

FIGS. 18(a), 18(b), and 18(c) are views schematically showing the substrate W in the solidified film forming step of Comparative Example Groups 1 and 2, respectively.

Reference is made to FIG. 18(a). In the solidified film forming step, the liquid film G starts to change to the solidified film K. The liquid film G gradually decreases. The liquid film G still remains on the substrate W. The solidified film K gradually grows.

Reference is made to FIG. 18(b). As described above, in Comparative Example Groups 1 and 2, the sublimable substance has a vapor pressure of more than 1.0 Pa at normal temperatures. Therefore, after the liquid film G starts to change to the solidified film K, the solidified film K starts to sublimate at an earlier timing. In other words, the time from when the liquid film G starts to change to the solidified film K to when the solidified film K starts to sublimate is short. After the liquid film G starts to change to the solidified film K, the solidified film K sublimates at a higher speed. In other words, the sublimation amount of the solidified film K per unit time is larger than the increase amount of the solidified film K per unit time. As a result, in the solidified film forming step, the thickness HK of the solidified film K does not become sufficiently large. Before the liquid film G disappears from the substrate W, the thickness HK of the solidified film K becomes remarkably thinner, for example. The thickness HK of the solidified film K becomes thinner than the thickness HG of the liquid film G, for example. Before the liquid film G disappears from the substrate W, the top face K1 of the solidified film K is lower than the tip W1d of the projection W1, for example.

In these cases, it is difficult for the solidified film K to appropriately support the projections W1. The pattern WP is easily affected by the liquid film G remaining on the substrate W. Therefore, the pattern WP collapses more easily. It is more difficult to protect the pattern WP.

Reference is made to FIG. 18(c). In the worst case, the solidified film K disappears from the substrate W before the liquid film G disappears from the substrate W. In this case, the top face G1 of the remaining liquid film G contacts the gas J. That is, the top face G1 again becomes a gas-liquid interface. The top face G1 intersects with the pattern WP. That is, the gas-liquid interface intersects the pattern WP. Therefore, the pattern WP receives the surface tension of the liquid film G. Accordingly, the pattern WP collapses very easily. It is extremely difficult to protect the pattern WP. As a result, in Comparative Example Groups 1 and 2, the width U1 of the first range T1 is less than 10. The width U2 of the second range T2 is less than 10. The first collapse rate D1 is equal to or more than the second reference value F2. The process window for the compounding ratio R is narrow.

As described above, in Comparative Example Groups 1 and 2, since the treatment liquid g contains the sublimable substance having a vapor pressure of more than 1.0 Pa at normal temperatures, the width U1 of the first range T1 is less than 10. In Comparative Example Groups 1 and 2, since the treatment liquid g contains the sublimable substance having a vapor pressure of more than 1.0 Pa at normal temperatures, the width U2 of the second range T2 is less than 10. In Comparative Example Groups 1 and 2, since the treatment liquid g contains the sublimable substance having a vapor pressure of more than 1.0 Pa at normal temperatures, the first collapse rate D1 is equal to or more than the second reference value F2. In Comparative Example Groups 1 and 2, since the treatment liquid g contains the sublimable substance having a vapor pressure of more than 1.0 Pa at normal temperatures, the process window for the compounding ratio R is narrow.

On the other hand, in Example Groups 1 and 2, the sublimable substance is 1.0 Pa or less at normal temperatures. Therefore, the timing at which the solidified film K starts to sublimate is later. In other words, the time from when the liquid film G starts to change to the solidified film K to when the solidified film K starts to sublimate is long. The sublimation rate of the solidified film K is lower. In other words, the sublimation amount of the solidified film K per unit time is smaller than the increase amount of the solidified film K per unit time. Therefore, in the solidified film forming step, the thickness HK of the solidified film K becomes sufficiently large. Until the liquid film G disappears from the substrate W, the thickness HK of the solidified film K is sufficiently large. Until the liquid film G disappears from the substrate W, the top face K1 of the solidified film K is higher than the tip W1d of the projection W1, for example. Therefore, the solidified film K appropriately supports the projections W1 until the liquid film G disappears from the substrate W. In other words, the solidified film K appropriately supports the projections W1 while the liquid film G remains on the substrate W. Therefore, the pattern WP is hardly affected by the liquid film G. The liquid film G is removed from the substrate W without applying any significant force to the substrate W. Therefore, the pattern WP hardly collapses. The pattern WP is appropriately protected. As a result, in Example Groups 1 and 2, the width U1 of the first range T1 is 10 or more. The width U2 of the second range T2 is 10 or more. The first collapse rate D1 is lower than the second reference value F2. The process window for the compounding ratio R is wide.

As described above, in Example Groups 1 and 2, since the treatment liquid g contains the sublimable substance having a vapor pressure of 1.0 Pa or less at normal temperatures, the width U1 of the first range T1 is 10 or more. In Example Groups 1 and 2, since the treatment liquid g contains the sublimable substance having a vapor pressure of 1.0 Pa or less at normal temperatures, the width U2 of the second range T2 is 10 or more. In Example Groups 1 and 2, since the treatment liquid g contains the sublimable substance having a vapor pressure of 1.0 Pa or less at normal temperatures, the first collapse rate D1 is lower than the second reference value F2. In Example Groups 1 and 2, since the treatment liquid g contains the sublimable substance having a vapor pressure of 1.0 Pa or less at normal temperatures, the process window for the compounding ratio R is wide.

The range of the compounding ratio R for appropriately treating the substrate W is one of the ranges of conditions of the treatment liquid g for appropriately treating the substrate W. The range of conditions of the treatment liquid g for appropriately treating the substrate W corresponds to the process window for the treatment liquid g. Therefore, the process window for the compounding ratio R is one of the process windows for the treatment liquid g.

In summary, the process window of the treatment liquid g containing the sublimable substance having a vapor pressure of 1.0 Pa or less at normal temperatures is wider than the process window of the treatment liquid g containing the sublimable substance having a vapor pressure of more than 1.0 Pa at normal temperatures.

In Example Groups 1 and 2, the sublimable substance has a vapor pressure of 0.1 Pa or more at normal temperatures. Therefore, in the sublimation step, the solidified film K appropriately sublimates. Accordingly, the treatment in the sublimation step does not require an excessively long time.

On the contrary, when the sublimable substance has a vapor pressure at normal temperatures of less than 0.1 Pa, the treatment in the sublimation step requires an excessively long time. Therefore, when the sublimable substance has a vapor pressure at normal temperatures of less than 0.1 Pa, the substrate treating method is not practical. When the sublimable substance has a vapor pressure at normal temperatures of less than 0.1 Pa, the throughput of the substrate treating method is significantly low.

### 9. Mechanism for Collapse of Pattern WP (2)

The Inventors observed how the liquid film G changed to the solidified film K in Example Groups 1 and 2 and Comparative Example Groups 1 and 2. Specifically, the Inventors photographed moving images of states in which the liquid film G is changed to the solidified film K in Example Groups 1 and 2 and Comparative Example Groups 1 and 2 with an optical microscope. Then, the Inventors compared and observed the respective moving images of Example Groups 1 and 2 and Comparative Example Groups 1 and 2. As a result, the following observation results were obtained.

Observation results: The solidified films K grew more rapidly in Comparative Example Groups 1 and 2 than in Example Groups 1 and 2. In other words, the solidified films K grew more slowly in Example Groups 1 and 2 than in Comparative Example Groups 1 and 2.

Meanwhile, the solubility Rm of Example Groups 1 and 2 is larger than the solubility Rm of Comparative Example Groups 1 and 2. In Example Groups 1 and 2, the solubility Rm is 150 vol % or more at normal temperatures. In Comparative Example Groups 1 and 2, the solubility Rm is less than 150 vol % at normal temperatures.

Based on the observation results and the solubility Rm described above, the Inventors have inferred the following matters. When the solubility Rm is small, the growth rate of the solidified film K is high. When the growth rate of the solidified film K is high, the pattern WP is likely to collapse. On the other hand, when the solubility Rm is large, the growth rate of the solidified film K is low. When the growth rate of the solidified film K is low, the pattern WP hardly collapses. Therefore, the solubility Rm is also one factor affecting the process window.

Specifically, the mechanism for collapse of the pattern WP assumed by the Inventors is as follows.

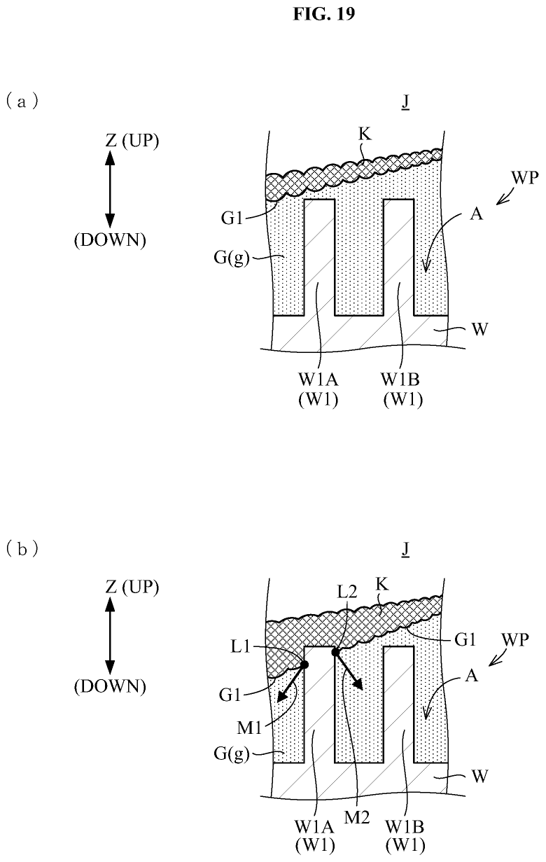

FIGS. 19(a) and 19(b) are views schematically showing the substrate W in the solidified film forming step of Comparative Example Groups 1 and 2, respectively.

Reference is made to FIG. 19(a). In Comparative Example Groups 1 and 2, the solidified film K grows rapidly. In Comparative Example Groups 1 and 2, the growth rate of the solidified film K is high. After the treatment liquid g is supplied to the substrate W, the liquid film G starts to change to the solidified film K at an earlier timing. For example, before the top face G1 of the liquid film G becomes flat, the liquid film G starts to change to the solidified film K. Therefore, the solidified film K does not extend horizontally. The solidified film K inclines.

In order to distinguish two projections W1 shown in FIG. 19(a), each projection W1 is referred to as first projection W1A and second projection W1B. The thickness of the solidified film K near the first projection W1A is larger than the thickness of the solidified film K near the second projection W1B. The growth of the solidified film K near the first projection W1A is faster than the growth of the solidified film K near the second projection W1B. As described above, the growth of the solidified film K is remarkably uneven over the substrate W.

Reference is made to FIG. 19(b). Also in FIG. 19(b), the solidified film K does not extend horizontally. Also in FIG. 19(b), the growth of the solidified film K is remarkably uneven over the substrate W.

The solidified film K contacts the first projection W1A. Specifically, both the liquid film G and the solidified film K contact the first projection W1A. The top face G1 of the liquid film G intersects with the first projection W1A. The top face G1 is an interface between the liquid film G and the solidified film K. Therefore, the first projection W1A receives capillary forces M1 and M2. The capillary force M1 acts on intersection L1 of the top face G1 and the first projection W1A. The capillary force M2 acts on intersection L2 of the top face G1 and the first projection W1A. The intersection L1 is not located at the same height as the intersection L2. The intersection L1 is lower than the intersection L2, for example. Therefore, the capillary force M1 and the capillary force M2 are not balanced with each other. The capillary force M1 and the capillary force M2 do not cancel each other. Therefore, the first projection W1A easily collapses by the capillary forces M1 and M2. As a result, in Comparative Example Groups 1 and 2, the process window of the treatment liquid g is even narrower.

As described above, in Comparative Example Groups 1 and 2, since the treatment liquid g has a solubility Rm of less than 150 vol % at normal temperatures, the process window of the treatment liquid g is even narrower.

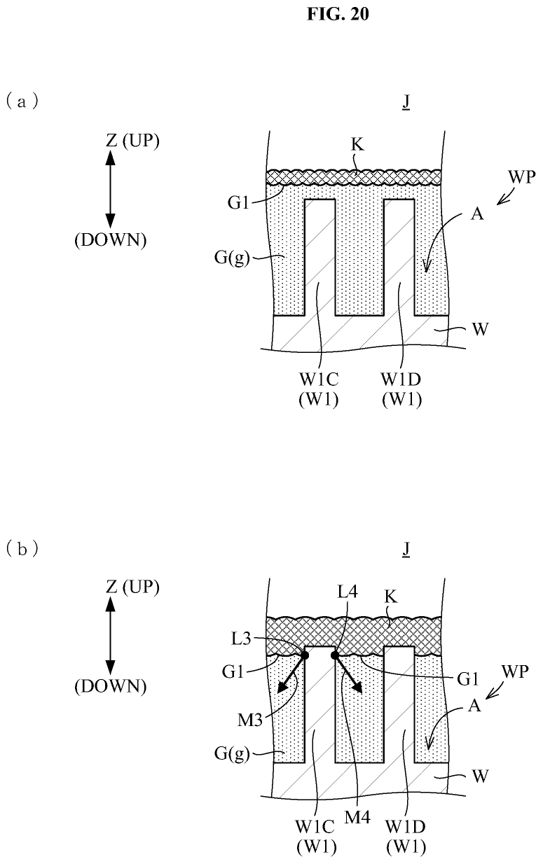

FIGS. 20(a) and 20(b) are views schematically showing the substrate W in the solidified film forming step of Example Groups 1 and 2, respectively.

Reference is made to FIG. 20(a). In Example Groups 1 and 2, the solidified film K grows slowly. In Example Groups 1 and 2, the growth rate of the solidified film K is low. After the treatment liquid g is supplied to the substrate W, the liquid film G starts to change to the solidified film K at a later timing. For example, after the top face G1 of the liquid film G becomes flat, the liquid film G starts to change to the solidified film K. Therefore, the solidified film K extends horizontally. The solidified film K does not incline.

In order to distinguish two projections W1 shown in FIG. 20(a), each projection W1 is referred to as third projection W1C and fourth projection W1D. The thickness of the solidified film K near the third projection W1C is substantially equal to the thickness of the solidified film K near the fourth projection W1D. The growth of the solidified film K near the third projection W1C is substantially equal to the growth of the solidified film K near the fourth projection W1D. As described above, the growth of the solidified film K is substantially uniform over the substrate W.

Reference is made to FIG. 20(b). Also in FIG. 20(b), the solidified film K extends horizontally. Also in FIG. 20(b), the growth of the solidified film K is substantially uniform over the substrate W.

The solidified film K contacts the third projection W1C. Specifically, both the liquid film G and the solidified film K contact the third projection W1C. The top face G1 of the liquid film G intersects with the third projection W1C. The top face G1 is an interface between the liquid film G and the solidified film K. Therefore, the third projection W1C receives the capillary forces M3 and M4. The capillary force M3 acts on intersection L3 of the top face G1 and the third projection W1C. The capillary force M4 acts on intersection L4 of the top face G1 and the third projection W1C. The intersection L3 is located at the same height as the intersection L4. Therefore, the capillary force M3 and the capillary force M4 are balanced with each other. The capillary force M3 and the capillary force M4 cancel each other. Therefore, the third projection W1C hardly collapses by the capillary forces M3 and M4. As a result, in Example Groups 1 and 2, the process window of the treatment liquid g is further wider.

As described above, in Example Groups 1 and 2, since the treatment liquid g has a solubility Rm of 150 vol % or more at normal temperatures, the process window of the treatment liquid g is further wider.

In summary, the process window of the treatment liquid g having a solubility Rm of 150 vol % or more at normal temperatures is further wider than the process window of the treatment liquid g having a solubility Rm of less than 150 vol % at normal temperatures.

### 10. Effect of Embodiment

The substrate treating method of the embodiment is for treating the substrate W on which the pattern WP is formed. The substrate treating method includes the treatment liquid supply step, the solidified film forming step, and the sublimation step. In the treatment liquid supply step, the treatment liquid g is supplied to the substrate W. The treatment liquid g contains the sublimable substance and the solvent. In the solidified film forming step, the solvent evaporates from the treatment liquid g on the substrate W. In the solidified film forming step, the solidified film K is formed on the substrate W. The solidified film K contains the sublimable substance. In the sublimation step, the solidified film K sublimates. The substrate W is dried by sublimation of the solidified film K.

Here, the sublimable substance has a vapor pressure at normal temperatures of 0.1 Pa or more and 1.0 Pa or less. Therefore, the conditions of the treatment liquid g for appropriately treating the substrate W are laxer. In other words, the process window for the treatment liquid g is wider. For example, the process window of the treatment liquid g containing the sublimable substance having a vapor pressure of 0.1 Pa or more and 1.0 Pa or less at normal temperatures is wider than the process window of the treatment liquid g containing the sublimable substance having a vapor pressure of more than 1.0 Pa at normal temperatures.

Therefore, it is easy to produce the treatment liquid g that satisfies the conditions of the treatment liquid g. It is easy to store the treatment liquid g in a state where the treatment liquid g satisfies the conditions of the treatment liquid g. It is easy to supply the treatment liquid g that satisfies the conditions of the treatment liquid g to the substrate W.

Therefore, it is easier to appropriately dry the substrate W.

As described above, according to this substrate treating method, the substrate W is appropriately dried.

The sublimable substance has a solubility Rm in the solvent of 150 vol % or more at normal temperatures. Therefore, the conditions of the treatment liquid g for appropriately treating the substrate W are even laxer. In other words, the process window for the treatment liquid g is further wider. For example, the process window of the treatment liquid g having a solubility Rm of 150 vol % or more at normal temperatures is further wider than the process window of the treatment liquid g having a solubility Rm of less than 150 vol % at normal temperatures. Therefore, it is further easier to appropriately dry the substrate W.

The sublimable substance is, for example 4-tert-butylphenol. 4-tert-butylphenol has a vapor pressure at normal temperatures of 0.1 Pa or more and 1.0 Pa or less. When the sublimable substance is 4-tert-butylphenol, it is suitably satisfied that the sublimable substance has a vapor pressure at normal temperatures of 0.1 Pa or more and 1.0 Pa or less. Therefore, the conditions of the treatment liquid g for appropriately treating the substrate W are laxer. Therefore, it is easier to appropriately dry the substrate W.

The sublimable substance is, for example, acetophenone oxime. Acetophenone oxime has a vapor pressure at normal temperatures of 0.1 Pa or more and 1.0 Pa or less. When the sublimable substance is acetophenone oxime, it is suitably satisfied that the sublimable substance has a vapor pressure at normal temperatures of 0.1 Pa or more and 1.0 Pa or less. Therefore, the conditions of the treatment liquid g for appropriately treating the substrate W are laxer. Therefore, it is easier to appropriately dry the substrate W.

The solvent is, for example, isopropyl alcohol. Solubility Rm of 4-tert-butylphenol in isopropyl alcohol is 150 vol % or more at normal temperatures. Solubility Rm of acetophenone oxime in isopropyl alcohol is 150 vol % or more at normal temperatures. When the solvent is isopropyl alcohol, it is easy to satisfy that the solubility Rm is 150 vol % or more at normal temperatures. Therefore, the conditions of the treatment liquid g for appropriately treating the substrate W are even laxer. Therefore, it is further easier to appropriately dry the substrate W.

When the compounding ratio R is within the first range T1, the collapse rate D is equal to or less than the first reference value F1. Here, the compounding ratio R is a ratio of the volume Q1g of the sublimable substance for producing the treatment liquid g to the volume Q2g of the solvent for producing the treatment liquid g. The collapse rate D is a probability that the pattern WP on the substrate W collapses when the substrate W is treated in the treatment liquid supply step, the solidified film forming step, and the sublimation step. The first reference value F1 is a value obtained by adding 5% to the minimum collapse rate Da. The minimum collapse rate Da is the smallest collapse rate D among the plurality of collapse rates D (%) obtained by changing the compounding ratio R. Therefore, when the compounding ratio R is within the first range T1, the collapse rate D is low. When the compounding ratio R is within the first range T1, the pattern WP on the substrate W is suitably protected. When the compounding ratio R is within the first range T1, the substrate W is appropriately dried.

The first range T1 has a width U1 of 10 or more. That is, the width U1 of the first range T1 is wide. Here, the compounding ratio R is one of the conditions of the treatment liquid g. The first range T1 corresponds to the range of conditions of the treatment liquid g. The first range T1 corresponds to the process window for the treatment liquid g. Therefore, the conditions of the treatment liquid g are lax. The process window for the treatment liquid g is wide. Therefore, it is easier to appropriately dry the substrate W.

In Example Group 1, for example, when the maximum height HM of the solidified film K is about 2.5 times the height HP of the pattern WP, the collapse rate D is equal to or less than the first reference value F1. The maximum height HM of the solidified film K depends on the compounding ratio R. When the maximum height HM of the solidified film K is about 2.5 times the height HP of the pattern WP, the substrate W is appropriately treated. This indicates that the process window for the treatment liquid g is even wider. As described above, the process window for the treatment liquid g is even wider. Therefore, it is even easier to appropriately dry the substrate W.

In Example Group 2, for example, when the maximum height HM of the solidified film K is about 4.0 times the height HP of the pattern WP, the collapse rate D is equal to or less than the first reference value F1. The maximum height HM of the solidified film K depends on the compounding ratio R. When the maximum height HM of the solidified film K is about 4.0 times the height HP of the pattern WP, the substrate W is appropriately treated. This indicates that the process window for the treatment liquid g is even wider. As described above, the process window for the treatment liquid g is even wider. Therefore, it is even easier to appropriately dry the substrate W.

When the compounding ratio R is the optimum compounding ratio Ra, the collapse rate D is the minimum collapse rate Da. When the compounding ratio R is the first compounding ratio R1, the collapse rate D is the first collapse rate D1. Here, the first compounding ratio R1 is a value obtained by adding 10 vol % to the optimum compounding ratio Ra.

The first collapse rate D1 is lower than the second reference value F2. Here, the second reference value F2 is a value obtained by adding 10% to the minimum collapse rate Da. Therefore, when the compounding ratio R increases from the optimum compounding ratio Ra by 10 vol %, the collapse rate D increases from the minimum collapse rate Da by less than 10%. In other words, when the increase amount of the compounding ratio R from the optimum compounding ratio Ra is 10%, the increase amount of the collapse rate D from the minimum collapse rate Da is less than 10%. Accordingly, when the compounding ratio R increases from the optimum compounding ratio Ra by 10 (vol %), the collapse rate D does not significantly increase. When the compounding ratio R increases from the optimum compounding ratio Ra by 10 (vol %), the increase amount of the collapse rate D is small. Therefore, when the compounding ratio R is equal to or more than the optimum compounding ratio Ra and equal to or less than the first compounding ratio R1, the substrate W is appropriately dried.

The range of the compounding ratio R from the optimum compounding ratio Ra to the first compounding ratio R1 is 10 vol %. That is, the range of the compounding ratio R from the optimum compounding ratio Ra to the first compounding ratio R1 is wide. Here, the compounding ratio R is one of the conditions of the treatment liquid g. The range of the compounding ratio R from the optimum compounding ratio Ra to the first compounding ratio R1 corresponds to the range of conditions of the treatment liquid g. The range of the compounding ratio R from the optimum compounding ratio Ra to the first compounding ratio R1 corresponds to the process window for the treatment liquid g. Therefore, the conditions of the treatment liquid g are lax. The process window for the treatment liquid g is wide. Therefore, it is easier to appropriately dry the substrate W.

The minimum collapse rate Da is 5% or less. When the minimum collapse rate Da is 5% or less, the first reference value F1 is 10% or less. Therefore, when the compounding ratio R is within the first range T1, the collapse rate D is 10% or less. When the compounding ratio R is within the first range T1, the collapse rate D is low. When the compounding ratio R is within the first range T1, the pattern WP on the substrate W is suitably protected. Therefore, it is easier to appropriately dry the substrate W.

Furthermore, when the minimum collapse rate Da is 5% or less, the second reference value F2 is 15% or less. When the minimum collapse rate Da is 5% or less, the first collapse rate D1 is less than 15%. Therefore, when the compounding ratio R is the optimum compounding ratio Ra, the collapse rate D is 5% or less. When the compounding ratio R is the first compounding ratio R1, the collapse rate D is less than 15%. Accordingly, when the compounding ratio R is within the range of the optimum compounding ratio Ra to the first compounding ratio R1, the collapse rate D is low. When the compounding ratio R is within the range of the optimum compounding ratio Ra to the first compounding ratio R1, the pattern WP on the substrate W is suitably protected. Therefore, it is easier to appropriately dry the substrate W.

The minimum collapse rate Da is 1% or less. When the minimum collapse rate Da is 1% or less, the first reference value F1 is 6% or less. Therefore, when the compounding ratio R is within the first range T1, the collapse rate D is 6% or less. When the compounding ratio R is within the first range T1, the collapse rate D is even lower. When the compounding ratio R is within the first range T1, the pattern WP on the substrate W is more suitably protected. Therefore, it is further easier to appropriately dry the substrate W.

Furthermore, when the minimum collapse rate Da is 1% or less, the second reference value F2 is 11% or less. When the minimum collapse rate Da is 1% or less, the first collapse rate D1 is less than 11%. Therefore, when the compounding ratio R is the optimum compounding ratio Ra, the collapse rate D is 1% or less. When the compounding ratio R is the first compounding ratio R1, the collapse rate D is less than 11%. Accordingly, when the compounding ratio is within the range from the optimum compounding ratio to the first compounding ratio, the collapse rate D is even lower. When the compounding ratio is within the range from the optimum compounding ratio to the first compounding ratio, the pattern WP on the substrate W is more suitably protected. Therefore, it is further easier to appropriately dry the substrate W.

When the compounding ratio R is within the second range T2, the collapse rate D is 20 (%) or less. Therefore, when the compounding ratio R is within the second range T2, the collapse rate D is low. When the compounding ratio R is within the second range T2, the pattern WP on the substrate W is suitably protected. When the compounding ratio R is within the second range T2, the substrate W is appropriately treated.

The second range T2 has a width U2 of 10 or more. That is, the width U2 of the second range T2 is wide. Here, the compounding ratio R is one of the conditions of the treatment liquid g. The second range T2 corresponds to the range of conditions of the treatment liquid g. The second range T2 corresponds to the process window for the treatment liquid g. Therefore, the conditions of the treatment liquid g are lax. The process window for the treatment liquid g is wide. Therefore, it is easier to appropriately dry the substrate W.

In Example Group 1, when the maximum height HM of the solidified film K is about 3.5 times the height HP of the pattern WP, the collapse rate D is 20% or less. The maximum height HM of the solidified film K depends on the compounding ratio. When the maximum height HM of the solidified film K is about 3.5 times the height HP of the pattern WP, the substrate W is appropriately treated. This indicates that the process window for the treatment liquid g is even wider. As described above, the process window for the treatment liquid g is even wider. Therefore, it is even easier to appropriately dry the substrate W.

In Example Group 2, when the maximum height HM of the solidified film K is about 4.0 times the height HP of the pattern WP, the collapse rate D is 20% or less. The maximum height HM of the solidified film K depends on the compounding ratio. When the maximum height HM of the solidified film K is about 4.0 times the height HP of the pattern WP, the substrate W is appropriately treated. This indicates that the process window for the treatment liquid g is even wider. As described above, the process window for the treatment liquid g is even wider. Therefore, it is even easier to appropriately dry the substrate W.

The substrate treating apparatus 1 includes the substrate holder 13 and the first supply unit 15a. The substrate holder 13 holds the substrate W. The first supply unit 15a supplies the treatment liquid g to the substrate W held by the substrate holder 13. The treatment liquid g contains the sublimable substance and the solvent. Therefore, when the treatment liquid g is supplied to the substrate W, the solvent is evaporated from the treatment liquid g on the substrate W. The solidified film K is formed on the substrate W by evaporation of the solvent. The solidified film K contains the sublimable substance. Therefore, the solidified film K sublimates. The substrate W is dried by sublimation of the solidified film K.

Here, the sublimable substance has a vapor pressure at normal temperatures of 0.1 Pa or more and 1.0 Pa or less. Therefore, the conditions of the treatment liquid g for appropriately treating the substrate W are laxer. In other words, the process window for the treatment liquid g is wider. For example, the process window of the treatment liquid g containing the sublimable substance having a vapor pressure of 0.1 Pa or more and 1.0 Pa or less at normal temperatures is wider than the process window of the treatment liquid g containing the sublimable substance having a vapor pressure of more than 1.0 Pa at normal temperatures. Therefore, it is easier to appropriately dry the substrate W.

As described above, according to the substrate treating apparatus 1, the substrate W is appropriately dried.

The sublimable substance has a solubility Rm in the solvent of 150 vol % or more at normal temperatures. Therefore, the conditions of the treatment liquid g for appropriately treating the substrate W are even laxer. In other words, the process window for the treatment liquid g is further wider. For example, the process window of the treatment liquid g having a solubility Rm of 150 vol % or more at normal temperatures is further wider than the process window of the treatment liquid g having a solubility Rm of less than 150 vol % at normal temperatures. Therefore, it is further easier to appropriately dry the substrate W.

The treatment liquid g is used for drying the substrate W on which the pattern WP is formed. Specifically, the treatment liquid g is the dry-assisting liquid. The treatment liquid g contains the sublimable substance and the solvent. The sublimable substance has a vapor pressure at normal temperatures of 0.1 Pa or more and 1.0 Pa or less. Therefore, the conditions of the treatment liquid g for appropriately treating the substrate Ware laxer. In other words, the process window for the treatment liquid g is wider. For example, the process window of the treatment liquid g containing the sublimable substance having a vapor pressure of 0.1 Pa or more and 1.0 Pa or less at normal temperatures is wider than the process window of the treatment liquid g containing the sublimable substance having a vapor pressure of more than 1.0 Pa at normal temperatures. Therefore, by using the treatment liquid g, it is easier to appropriately dry the substrate W. Specifically, by using the treatment liquid g, it is easier to dry the substrate W while suitably protecting the pattern WP on the substrate W. By using the treatment liquid g, it is easier to prevent collapse of the pattern WP in the dry treatment of the substrate W. As described above, the treatment liquid g is useful for drying the substrate W.

As described above, the substrate W is appropriately dried using the treatment liquid g.

The sublimable substance has a solubility Rm in the solvent g of 150 vol % or more at normal temperatures. Therefore, the conditions of the treatment liquid g for appropriately treating the substrate W are even laxer. In other words, the process window for the treatment liquid g is further wider. For example, the process window of the treatment liquid g having a solubility Rm of 150 vol % or more at normal temperatures is further wider than the process window of the treatment liquid g having a solubility Rm of less than 150 vol % at normal temperatures. Therefore, it is further easier to appropriately dry the substrate W using the treatment liquid g. Therefore, the substrate W is more appropriately dried using the treatment liquid g.

The sublimable substance is, for example 4-tert-butylphenol. 4-tert-butylphenol has a vapor pressure at normal temperatures of 0.1 Pa or more and 1.0 Pa or less. When the sublimable substance is 4-tert-butylphenol, it is suitably satisfied that the sublimable substance has a vapor pressure at normal temperatures of 0.1 Pa or more and 1.0 Pa or less. Therefore, the conditions of the treatment liquid g for appropriately treating the substrate W are laxer. Therefore, it is easier to appropriately dry the substrate W using the treatment liquid g.

The sublimable substance is, for example, acetophenone oxime. Acetophenone oxime has a vapor pressure at normal temperatures of 0.1 Pa or more and 1.0 Pa or less. When the sublimable substance is acetophenone oxime, it is suitably satisfied that the sublimable substance has a vapor pressure at normal temperatures of 0.1 Pa or more and 1.0 Pa or less. Therefore, the conditions of the treatment liquid g for appropriately treating the substrate W are laxer. Therefore, it is easier to appropriately dry the substrate W using the treatment liquid g.

The solvent is, for example, isopropyl alcohol. Solubility Rm of 4-tert-butylphenol in isopropyl alcohol is 150 vol % or more at normal temperatures. Solubility Rm of acetophenone oxime in isopropyl alcohol is 150 vol % or more at normal temperatures. When the solvent is isopropyl alcohol, it is easy to control the solubility Rm to 150 vol % or more at normal temperatures. Therefore, the conditions of the treatment liquid g for appropriately treating the substrate W are even laxer. Therefore, it is easier to appropriately dry the substrate W using the treatment liquid g.

### 11. Modified Embodiment

The present invention is not limited to the embodiment, and can be modified as follows.

(1) In the embodiment, the sublimable substance was, for example, 4-tert-butylphenol. In the embodiment, the sublimable substance was, for example, acetophenone oxime. However, the present invention is not limited thereto. The sublimable substance may be appropriately changed to another compound. Also in the present modification, the sublimable substance preferably has a vapor pressure of 0.1 Pa or more and 1.0 Pa or less at normal temperatures.

(2) In the embodiment, the solvent was, for example, isopropyl alcohol (IPA). However, the present invention is not limited thereto. The solvent may be appropriately changed to another compound. Also in the present modification, the ability of the solvent to dissolve the sublimable substance is preferably high.

(3) In the embodiment, the collapse rate D was a median dm in a plurality of local collapse rates di. However, the present invention is not limited thereto. For example, the collapse rate D may be, for example, an average value da of the plurality of local collapse rates di. Alternatively, the collapse rate D may be a ratio of the sum of the numbers NTi in each local area Ei to the sum of the numbers NPi in each local area Ei.

(4) In the embodiment, the treatment liquid condition information includes the target for the compounding ratio R. However, the present invention is not limited thereto. For example, the treatment liquid condition information may include, for example, a target for the initial concentration V0. The target for the initial concentration V0 may be defined by one value. The target for the initial concentration V0 may be defined by a range between two different values.

(5) In the embodiment, the treatment liquid g was produced before the treatment liquid g is supplied to the first supply unit 15a. In the embodiment, the first supply source 19a produced the treatment liquid g in the tank 22. However, the present invention is not limited thereto. For example, the treatment liquid g may be produced when the treatment liquid g is supplied to the first supply unit 15a. For example, the first supply source 19a may produce the treatment liquid g in a flow path for supplying the treatment liquid g to the first supply unit 15a.

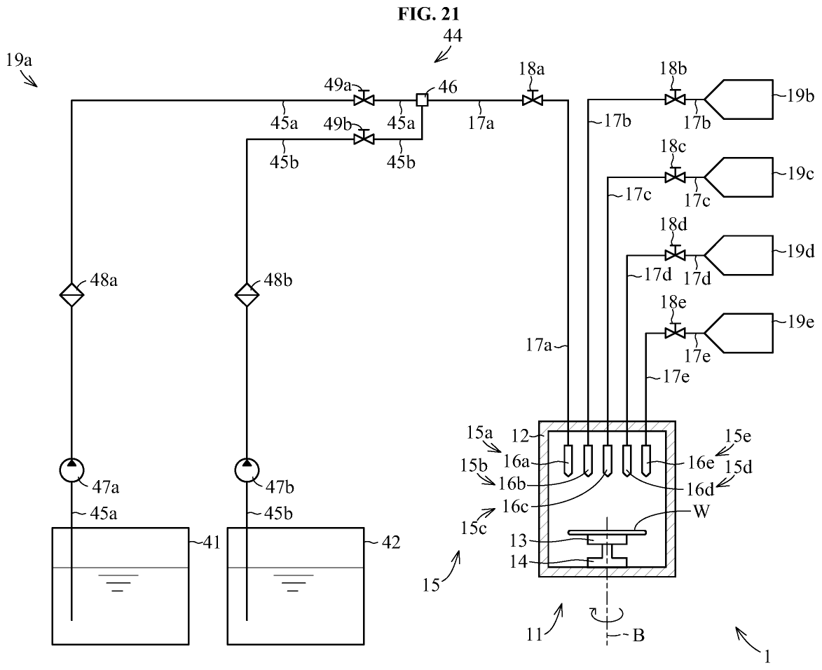

FIG. 21 is a diagram showing a construction of a treating unit 11 and a first supply source 19a according to the modified embodiment. Like numerals are used to identify like components which are the same as those in the embodiment, and the components will not particularly be described.

The first supply source 19a includes a first tank 41 and a second tank 42. The first tank 41 stores the sublimable substance. For example, the first tank 41 may store the solvent together with the sublimable substance. The second tank 42 stores the solvent. For example, the second tank 42 stores only the solvent.

The first supply source 19a includes a mixing unit 44. The mixing unit 44 is connected to the first tank 41 and the second tank 42. The mixing unit 44 is in fluid communication with the first tank 41 and the second tank 42. The mixing unit 44 produces a treatment liquid g.

The mixing unit 44 is connected to the first supply unit 15a. The mixing unit 44 is in fluid communication with the first supply unit 15a. The mixing unit 44 supplies the treatment liquid g to the first supply unit 15a.

Specifically, the mixing unit 44 includes pipes 45a and 45b and a joint 46. The pipe 45a is connected to the first tank 41. The pipe 45a is in fluid communication with the first tank 41. The pipe 45b is connected to the second tank 42. The pipe 45b is in fluid communication with the second tank 42. The joint 46 is connected to the pipes 45a and 45b. The joint 46 is in fluid communication with the pipes 45a and 45b. The joint 46 is also connected to the pipe 17a. The joint 46 is also in fluid communication with the pipe 17a. The pipes 45a and 45b are connected to the pipe 17a via the joint 46. The pipes 45a and 45b are in fluid communication with the pipe 17a via the joint 46.

The mixing unit 44 includes pumps 47a and 47b. The pumps 47a and 47b are provided on the pipes 45a and 45b, respectively. The pump 47a feeds the sublimable substance from the first tank 41 to the joint 46 through the pipe 45a. The pump 47b feeds the solvent from the second tank 42 to the joint 46 through the pipe 45b.

The mixing unit 44 includes filters 48a and 48b. The filters 48a and 48b are provided on the pipes 45a and 45b, respectively. The sublimable substance passes through the filter 48a. The filter 48a filters the sublimable substance. The solvent passes through the filter 48b. The filter 48b filters the solvent.

The mixing unit 44 includes valves 49a and 49b. The valves 49a and 49b are provided on the pipes 45a and 45b, respectively. The valve 49a adjusts the flow rate of the sublimable substance flowing through the pipe 45a. The valve 49b adjusts the flow rate of the solvent flowing through the pipe 45b. Each of the valves 49a and 49b may include, for example, a flow rate control valve. Each of the valves 49a and 49b may include, for example, a flow rate control valve and an on-off valve.

The following describes one example of operation of the first supply source 19a in the modified embodiment. In the treatment liquid supply step, the first supply source 19a produces the treatment liquid g and feeds the treatment liquid g to the first supply unit 15a. Specifically, the valves 49a and 49b open. The pump 47a feeds the sublimable substance from the first tank 41 to the joint 46. The pump 47a pressure-feeds the sublimable substance from the first tank 41 to the joint 46. The pump 47b feeds the solvent from the second tank 42 to the joint 46. The pump 47b pressure-feeds the solvent from the second tank 42 to the joint 46. The sublimable substance and the solvent are mixed in the joint 46. The sublimable substance and the solvent become the treatment liquid g in the joint 46. Further, the treatment liquid g flows from the joint 46 to the first supply unit 15a. The nozzle 16a dispenses the treatment liquid g.

According to this modification, it is not necessary to store the treatment liquid g before the treatment liquid g is supplied to the first supply unit 15a. Therefore, the compounding ratio R of the treatment liquid g is accurately controlled. Accordingly, it is further easier for the treatment liquid g to satisfy the conditions of the treatment liquid g. The substrate W is more appropriately dried.

Furthermore, the first supply source 19a does not include the tank 22. Therefore, the structure of the first supply source 19a is suitably simplified. The first supply source 19a is suitably downsized.

(6) The substrate treating method according to the embodiment included a chemical liquid supply step, a rinse liquid supply step, and a replacement solution supply step. However, the present invention is not limited thereto. For example, at least one of the chemical liquid supply step, the rinse liquid supply step, and the replacement solution supply step may be omitted. For example, all of the chemical liquid supply step, the rinse liquid supply step, and the replacement solution supply step may be omitted.

(7) In the embodiment, when the treatment liquid supply step was executed, a liquid (for example, a replacement solution) existed on the substrate W. That is, in the treatment liquid supply step, the treatment liquid g is supplied to the substrate W in a non-dried state. However, the present invention is not limited thereto. For example, when the treatment liquid supply step is executed, a liquid (for example, a replacement solution) may not exist on the substrate W. For example, in the treatment liquid supply step, the treatment liquid g may be supplied to the substrate W in a dried state.

(8) In the treatment liquid supply step of the embodiment, the treatment liquid g removes the replacement solution from the substrate W. However, the present invention is not limited thereto. For example, in the treatment liquid supply step, the treatment liquid g may clean the substrate W. For example, in the treatment liquid supply step, the treatment liquid g may remove foreign substances adhering to the substrate W. For example, in the treatment liquid supply step, the treatment liquid g may dissolve foreign substances adhering to the substrate W. The foreign substance is, for example, a resist residue.

(9) In the solidified film forming step of the embodiment, the dry gas was not supplied to the substrate W. However, the present invention is not limited thereto. In the solidified film forming step, the dry gas may be supplied to the substrate W. In the solidified film forming step, the dry gas may be supplied to the treatment liquid g on the substrate W. According to this modification, in the solidified film forming step, the treatment liquid g on the substrate W is exposed to the dry gas. Accordingly, in the solidified film forming step, the solvent efficiently evaporates from the treatment liquid g on the substrate W. In the solidified film forming step, the solidified film K is efficiently formed on the substrate W.

(10) In the embodiment, for example, the pattern WP on the substrate W may be formed on the substrate W before the treating unit 11 treats the substrate W. Alternatively, when the treating unit 11 treats the substrate W, the pattern WP may be formed on the substrate W. The pattern WP may be formed on the substrate W, for example, in the chemical liquid supply step (step S12).

(11) The embodiment and each of the modified embodiments described in (1) to (10) above may be further varied as appropriate by replacing or combining their constructions with the constructions of the other modified embodiments.

### REFERENCE SIGNS LIST

1 substrate treating apparatus
10 controller
11 treating unit
13 substrate holder
15 supply unit
15a first supply unit (treatment liquid supply unit)
19a first supply source
A recess
D collapse rate (%)
D1 first collapse rate (%)
Da minimum collapse rate (%)
F1 first reference value (%)
F2 second reference value (%)
g treatment liquid
G liquid film of treatment liquid
G1 top face of liquid film
HG thickness of liquid film
HK thickness of solidified film
HM maximum height of solidified film (initial height of solidified film)
HP height of projection (height of pattern)
K solidified film
K1 top face of solidified film
Q1g volume of sublimable substance for producing treatment liquid
Q2g volume of solvent for producing treatment liquid
R compounding ratio (vol %)
Rm solubility of sublimable substance in solvent (vol %)
T1 first range
T2 second range
U1 width of first range
U2 width of second range
W substrate
WP pattern
W1 projection
W1p base end of projection
W1d tip of projection

1. A substrate treating method for treating a substrate on which a pattern is formed, the substrate treating method comprising:
a treatment liquid supply step of supplying a treatment liquid containing a sublimable substance and a solvent to the substrate;
a solidified film forming step of forming a solidified film containing the sublimable substance on the substrate by evaporating the solvent from the treatment liquid on the substrate; and
a sublimation step of sublimating the solidified film, and
the sublimable substance having a vapor pressure at normal temperatures of 0.1 Pa or more and 1.0 Pa or less.

2. The substrate treating method according to claim 1, wherein
the sublimable substance has a solubility in the solvent of 150 vol % or more at normal temperatures.

3. The substrate treating method according to claim 1, wherein
the sublimable substance is 4-tert-butylphenol.

4. The substrate treating method according to claim 1, wherein
the sublimable substance is acetophenone oxime.

5. The substrate treating method according to claim 1, wherein
the solvent is isopropyl alcohol.

6. The substrate treating method according to claim 1, wherein
a ratio of a volume of the sublimable substance for producing the treatment liquid to a volume of the solvent for producing the treatment liquid is defined as a compounding ratio (vol %),
a probability that the pattern on the substrate collapses when the substrate is treated in the treatment liquid supply step, the solidified film forming step, and the sublimation step is defined as a collapse rate (%),
the smallest collapse rate among the plurality of collapse rates (%) obtained by changing the compounding ratio is defined as a minimum collapse rate (%),
a value obtained by adding 5% to the minimum collapse rate is defined as a first reference value (%), and
a range of the compounding ratio when the collapse rate is equal to or less than the first reference value is defined as a first range, and
the first range has a width of 10 or more.

7. The substrate treating method according to claim 1, wherein
a ratio of a volume of the sublimable substance for producing the treatment liquid to a volume of the solvent for producing the treatment liquid is defined as a compounding ratio (vol %),
a probability that the pattern on the substrate collapses when the substrate is treated in the treatment liquid supply step, the solidified film forming step, and the sublimation step is defined as a collapse rate (%),
the smallest collapse rate among the plurality of collapse rates (%) obtained by changing the compounding ratio is defined as a minimum collapse rate (%),
the compounding ratio when the collapse rate is the minimum collapse rate is defined as an optimum compounding ratio (vol %),
a value obtained by adding 10 vol % to the optimum compounding ratio is defined as a first compounding ratio (vol %),
the collapse rate when the compounding ratio is the first compounding ratio is defined as a first collapse rate (%), and
a value obtained by adding 10% to the minimum collapse rate is defined as a second reference value (%), and
the first collapse rate is lower than the second reference value.

8. The substrate treating method according to claim 1, wherein
a ratio of a volume of the sublimable substance for producing the treatment liquid to a volume of the solvent for producing the treatment liquid is defined as a compounding ratio (vol %),
a probability that the pattern on the substrate collapses when the substrate is treated in the treatment liquid supply step, the solidified film forming step, and the sublimation step is defined as a collapse rate (%), and
a range of the compounding ratio when the collapse rate is 20 (%) or less is defined as a second range, and
the second range has a width of 10 or more.

9. A substrate treating apparatus comprising:
a substrate holder that holds a substrate; and
a treatment liquid supply unit that supplies a treatment liquid containing a sublimable substance and a solvent to the substrate held by the substrate holder, and
the sublimable substance having a vapor pressure at normal temperatures of 0.1 Pa or more and 1.0 Pa or less.

10. The substrate treating apparatus according to claim 9, wherein
the sublimable substance has a solubility in the solvent of 150 vol % or more at normal temperatures.

11. A treatment liquid used for drying a substrate on which a pattern is formed,
the treatment liquid containing:
a sublimable substance; and
a solvent, and
the sublimable substance having a vapor pressure at normal temperatures of 0.1 Pa or more and 1.0 Pa or less.

12. The treatment liquid according to claim 11, wherein
the sublimable substance has a solubility in the solvent of 150 vol % or more at normal temperatures.

13. The treatment liquid according to claim 11, wherein
the sublimable substance is 4-tert-butylphenol.

14. The treatment liquid according to claim 11, wherein
the sublimable substance is acetophenone oxime.

15. The treatment liquid according to claim 1, wherein
the solvent is isopropyl alcohol.
